(19) United States
(12) Patent Application Publication
(10) Pub. No.: US 2024/0229293 A1
(43) Pub. Date: Jul. 11, 2024

(54) PHASE STABILIZED GROWTH OF MONOCLINIC-GALLIUM OXIDE ON THERMALLY CONDUCTING MATERIALS

(71) Applicant: University of South Carolina, Columbia, SC (US)

(72) Inventors: Iftikhar Ahmad, Irmo, SC (US); Mohi Uddin Jewel, West Columbia, SC (US); Samiul Hasan, Columbia, SC (US)

(73) Assignee: University of South Carolina, Columbia, SC (US)

(21) Appl. No.: 18/506,315

(22) Filed: Nov. 10, 2023

Related U.S. Application Data
(60) Provisional application No. 63/479,384, filed on Jan. 11, 2023.

(51) Int. Cl. C30B 25/18; C30B 29/16; H01L 21/02

(52) U.S. Cl. CPC C30B 25/183; C30B 29/16; H01L 21/0242; H01L 21/02458; H01L 21/02565; H01L 21/0262

(57) ABSTRACT

Described herein are alternative uses of silicon for β-Ga₂O₃ MOCVD heteroepitaxy as a phase stabilizer in the form of silicon-oxygen (Si—O) bonding that provides thermal annealing for achieving smooth and thick monoclinic phase-pure gallium oxide (β-Ga₂O₃) on sapphire, which can provide β-Ga₂O₃ growth on thermally conductive hexagonal substrates, such as AlN, 4H—SiC, and 6H—SiC.

### STATEMENT REGARDING FEDERALLY SPONSORED RESEARCH

This invention was made with government support under Grant Number 2124624, awarded by the National Science Foundation. The government has certain rights in the invention.

### TECHNICAL FIELD

The subject matter disclosed herein is generally directed to alternative uses of silicon for β-Ga₂O₃ MOCVD heteroepitaxy as a phase stabilizer in the form of silicon-oxygen (Si—O) bonding that provides thermal annealing for achieving smooth and thick monoclinic phase-pure gallium oxide (β-Ga₂O₃) on sapphire, which can provide β-Ga₂O₃ growth on thermally conductive hexagonal substrates, such as AlN, 4H—SiC, and 6H—SiC.

### BACKGROUND

Different gallium oxide (Ga₂O₃) phases belong to the wide bandgap semiconductor category and have numerous applications. See, G. Seryogin, F. Alema, N. Valente, H. Fu, E. Steinbrunner, A. T. Neal, S. Mou, A. Fine, and A. Osinsky, Appl. Phys. Lett. 117, 262101 (2020), S. Ghose, S. Rahman, L. Hong, J. S. Rojas-Ramirez, H. Jin, K. Park, R. Klie, and R. Droopad, J. Appl. Phys. 122, 95302 (2017), J. H. Leach, K. Udwary, J. Rumsey, G. Dodson, H. Splawn, and K. R. Evans, APL Mater. 7, 22504 (2019), Y. Yao, S. Okur, L. A. M. Lyle, G. S. Tompa, T. Salagaj, N. Sbrockey, R. F. Davis, and L. M. Porter, Mater. Res. Lett. 6, 268 (2018), M. Uddin Jewel, S. Hasan, and I. Ahmad, Comput. Mater. Sci. 218, 111950 (2023), N. Makeswaran, A. K. Battu, E. Deemer, and C. V Ramana, Cryst. Growth Des. 20, 2893 (2020), F. Akyol and I. Demir, Mater. Sci. Semicond. Process. 146, 106645 (2022), A. K. Singh, M. Gupta, V. Sathe, and Y. S. Katharria, Superlattices Microstruct. 156, 106976 (2021). The monoclinic or β-Ga₂O₃ phase with a bandgap of ˜4.9 eV, a breakdown field of ˜8 MV/cm, and a Baliga figure-of-merit of 3400, is particularly notable. See G. Seryogin et al. The growth of monoclinic β-Ga₂O₃ and their alloys have been reported using different techniques. See, S. Ghose et al, M. D. Mia, B. C. Samuels, M. A. A. Talukder, P. D. Borges, L. Scolfaro, W. J. Geerts, and R. Droopad, J. Cryst. Growth 575, 126353 (2021), and W. Tang, Y. Ma, X. Zhang, X. Zhou, L. Zhang, X. Zhang, T. Chen, X. Wei, W. Lin, D. H. Mudiyanselage, H. Fu, and B. Zhang, Appl. Phys. Lett. 120, 212103 (2022). It is challenging to grow high-quality thick β-Ga₂O₃ and related alloys on foreign substrates. The majority of the heteroepitaxial films reported in the literature have been limited to thicknesses ranging 50-300 nm due to increased surface roughness with thickness S. Ghose et al, A. K. Singh et al, M. D. Mia et al, F. Egyenes-Pörsök, F. Gucmann, K. Hušeková, E. Dobročka, M. Sobota, M. Mikolášek, K. Fröhlich, and M. Ťapajna, Semicond. Sci. Technol. 35, 115002 (2020), D. Gogova, G. Wagner, M. Baldini, M. Schmidbauer, K. Irmscher, R. Schewski, Z. Galazka, M. Albrecht, and R. Fornari, J. Cryst. Growth 401, 665 (2014), and S. Nakagomi and Y. Kokubun, J. Cryst. Growth 349, 12 (2012). However, high-power devices require sufficiently thick (>1 μm) layers, for processable device structure, on thermally conductive substrates. See, M. D. Alam, M. Gaevski, M. U. Jewel, S. Mollah, A. Mamun, K. Hussain, R. Floyd, G. Simin, M. V. S. Chandrashekhar, and A. Khan, Appl. Phys. Lett. 119, 132106 (2021). The MOCVD method is extensively used for the homoepitaxial growth of β-Ga₂O₃. See, G. Seryogin et al. and W. Tang et al. Homoepitaxy of β-Ga₂O₃ suffers from the formation of oxygen-deficient gallium suboxide Ga₂O by decomposing Ga₂O₃ in (001), (010) growth direction, see, W. Tang et al., the limited diffusion length of adatoms a large number of twins and stacking faults in the (100), and (2̅01) direction, see, S. Jang, S. Jung, K. Beers, J. Yang, F. Ren, A. Kuramata, S. J. Pearton, and K. H. Baik, J. Alloys Compd. 731, 118 (2018) and A. F. M. Anhar Uddin Bhuiyan, Z. Feng, J. M. Johnson, H.-L. Huang, J. Hwang, and H. Zhao, Cryst. Growth Des. 20, 6722 (2020), thus, making it difficult to grow thick homoepitaxial β-Ga₂O₃. Tang et al. reported a root-mean-square (RMS) roughness of 24.7 nm on a 620 nm thick β-Ga₂O₃ grown on (001) β-Ga₂O₃ substrate. See, W. Tang et al. To the best of our knowledge, Seryogin et al. reported the lowest roughness (R_{q}) of 1.8 nm for a 2.3 μm thick film grown on (010) β-Ga₂O₃ substrate. See, G Seryogin et al. To date, most of the high-performance β-Ga₂O₃ devices have also been reported on (010) β-Ga₂O₃ substrates. See, S. Sharma, K. Zeng, S. Saha, and U. Singisetti, IEEE Electron Device Lett. 41, 836 (2020). The growth on native β-Ga₂O₃ substrates is not a viable option for high-power devices due to their scarcity, high cost, and extremely low thermal conductivity (˜0.27 W/cm·K). See, Y. Song, P. Ranga, Y. Zhang, Z. Feng, H.-L. Huang, M. D. Santia, S. C. Badescu, C. U. Gonzalez-Valle, C. Perez, K. Ferri, R. M. Lavelle, D. W. Snyder, B. A. Klein, J. Deitz, A. G. Baca, J.-P. Maria, B. Ramos-Alvarado, J. Hwang, H. Zhao, X. Wang, S. Krishnamoorthy, B. M. Foley, and S. Choi, ACS Appl. Mater. Interfaces 13, 38477 (2021). The inexpensive c-plane sapphire (α-Al₂O₃) substrates are more desirable for high-power devices due to their availability and compatibility with existing III-nitride process technology. It is noted that the thermal conductivity of c-plane sapphire is also not good.

Many efforts have been expanded toward the growth of phase stable thick Ga₂O₃ and other oxides (Hafnia HfO₂, Zirconia ZrO₂) by incorporating different elements (e.g., In, Si, Y). Zang et al. were able to inhibit the formation of Ga₂O caused by the decomposition of β-Ga₂O₃ [Reaction: 2Ga(l)+3/2O₂(g)⇄Ga₂O₃ (s), and 4Ga(l)+Ga₂O₃(s)⇄3Ga₂O(g)], and in the process achieve step-flow growth mode in (001) β-Ga₂O₃ homoepitaxy using indium as a surfactant. See, W. Tang, et al. Böscke et al. were able to stabilize tetragonal HfO₂ instead of monoclinic/tetragonal mixed phase HfO₂ by introducing a trace amount of silicon (<4%) forming silicon-oxygen bonding (SiOₓ) which reduced the stability of monoclinic HfO₂ and favored controlled crystallization of ferroelectric tetragonal phase. See, K. Tomida, K. Kita, and A. Toriumi, Appl. Phys. Lett. 89, 142902 (2006) and K. A. Mengle, G. Shi, D. Bayerl, and E. Kioupakis, Appl. Phys. Lett. 109, 212104 (2016). A common method of achieving 0.5-1 μm thick Ga₂O₃ is by growing amorphous or mixed phase Ga₂O₃ films followed by annealing at temperatures ≥900° C. to create a stable β-Ga₂O₃, see, C.-Y. Huang, R.-H. Horng, D.-S. Wuu, L.-W. Tu, and H.-S. Kao, Appl. Phys. Lett. 102, 11119 (2013) and J. Lee, H. Kim, L. Gautam, K. He, X. Hu, V. P. Dravid, and M. Razeghi, in Photonics (MDPI, 2021), p. 17., which is not a suitable option, as discussed herein.

Accordingly, it is an object of the present disclosure to provide MOCVD growth of thick phase-pure β-Ga₂O₃ on c-plane sapphire by introducing silicon-oxygen bonding. A ˜580 nm thick layer of β-Ga₂O₃ with silane was grown on a sapphire substrate and compared with ˜400 nm thick as-grown and annealed Ga₂O₃ films grown without silane. The successful heteroepitaxy of thick Ga₂O₃ can lead to its growth on thermally conductive hexagonal substrates like silicon carbide (SiC), aluminum nitride (AlN), etc. The β-Ga₂O₃ grows in the (2̅01) direction on c-plane sapphire. See, S. Ghose et al. and S. Nakagomi et al. Ga₂O₃ grown using the standard MOCVD results in an orthorhombic/monoclinic mixed phase on sapphire at 700° C. See, F. Egyenes-Pörsök et al.

Citation or identification of any document in this application is not an admission that such a document is available as prior art to the present disclosure.

### SUMMARY

The above objectives are accomplished according to the present disclosure by providing a method for growing Ga₂O₃ Growth on sapphire. The method may include employing a metal-organic chemical vapor deposition reactor, introducing at least one sapphire template to the reactor, using nitrogen as a carrier gas in the reactor to enable nitridation of the sapphire substrate, introducing Trimethylaluminum as a nitrogen precursor and ammonia as an aluminum precursor to the reactor to form an aluminum nitrogen layer on the at least one sapphire template, introducing Triethylgallium as a gallium precursor and oxygen as an oxygen precursor using nitrogen as a carrier gas in the reactor to form at least one gallium oxygen layer on the aluminum nitrogen layer, and employing silane in the reactor as a silicon precursor contemporaneous with introduction of the Triethylgallium and the oxygen in the reactor. Further, reactor pressure and substrate temperature may be kept constant throughout growth. Still further, the aluminum nitrogen layer may be formed via pulsed mode growth. Even further, the at least one gallium oxygen layer may include at least one β-Ga₂O₃ layer. Yet again, the at least one β-Ga₂O₃ layer may be monoclinic phase-pure gallium oxide. Still yet again, the method may include forming at least one SiOₓ complex in the at least one β-Ga₂O₃ via the introduction of silane into the reactor contemporaneous with the introduction of the Triethylgallium and the oxygen. Further again, the method may include forming sixfold inplane rotational symmetry in the at least one β-Ga₂O₃ layer formed on the aluminum nitrogen layer. Still again, the method may not include thermal annealing. Further yet again, the sapphire template may be c-plane sapphire.

In another aspect, another method for growing Ga₂O₃ layers on sapphire is provided. The method may include employing a metal-organic chemical vapor deposition reactor, introducing at least one sapphire template to the reactor, using nitrogen as a carrier gas in the reactor to enable nitridation of the sapphire substrate, forming at least one substrate layer onto the sapphire substrate wherein the at least one substrate layer comprises an aluminum nitrogen layer, a gallium nitrogen layer or a silicon carbon layer, introducing Triethylgallium as a gallium precursor and oxygen as an oxygen precursor using nitrogen as a carrier gas in the reactor to form at least one gallium oxygen layer on the aluminum nitrogen layer, and employing silane in the reactor as a silicon precursor contemporaneous with introduction of the Triethylgallium and the oxygen in the reactor. Further, reactor pressure and substrate temperature may be kept constant throughout growth. Even further, the aluminum nitrogen layer may be formed via pulsed mode growth. Still further, the at least one gallium oxygen layer may include at least one β-Ga₂O₃ layer. Further again, the at least one β-Ga₂O₃ layer may include monoclinic phase-pure gallium oxide. Still again, the method may include comprising forming a SiOₓ complex in the at least one β-Ga₂O₃ layer via the introduction of silane into the reactor contemporaneous with the introduction of Triethylgallium and introduction of the oxygen. Still yet again, the method may include forming sixfold inplane rotational symmetry in the at least one β-Ga₂O₃ layer formed on the aluminum nitrogen layer. Again still, the method may not include thermal annealing. Moreover, the sapphire template may be c-plane sapphire.

These and other aspects, objects, features, and advantages of the example embodiments will become apparent to those having ordinary skill in the art upon consideration of the following detailed description of example embodiments.

### BRIEF DESCRIPTION OF THE DRAWINGS

An understanding of the features and advantages of the present disclosure will be obtained by reference to the following detailed description that sets forth illustrative embodiments, in which the principles of the disclosure may be utilized, and the accompanying drawings of which:

FIG. 1 shows schematics of epitaxial structures.

FIG. 2 shows that SIMS analysis confirms the presence of SiOₓ complex.

FIG. 3 shows samples displaying uniform and continuous morphologies over the entire surface.

FIG. 4 shows micro-Raman spectra of the Ga₂O₃ grown without and with SiH₄.

FIG. 5 shows Table 1.

FIG. 6 shows at: (a) UV transmittance spectra of annealed Ga₂O₃ thin films, (b) XRD 2θ-ω spectra of the same, and (c) 2θ-ω spectra of (6̅03) peak.

FIG. 7 shows SIMS profiles of A1, C, Ga, O, Si elements, —CH, and SiOₓ complexes in Ga2O3 thin film annealed at 1000° C. for 30 minutes.

FIG. 8 shows surface AFM images of Ga2O3 thin films annealed for 30 minutes at (a) 1000° C., and (b) 1100° C. Top-view SEM images of the same annealed for 30 minutes at (c) 1000° C., and (d) 1100° C.

FIG. 9 shows Table 2—properties of Ga₂O₃ thin films grown at various conditions.

FIG. 10 shows a schematic of Ga₂O₃ epilayers on sapphire: a) without SiH₄ (sample A1, A2, A3); b) with SiH₄ (sample B1), and on AlN/sapphire templates; c) without SiH4 (sample A4); and d) with SiH₄ (sample B2).

FIG. 11 shows Ga₂O₃ thin films: a) UV transmittance spectra (inset shows the (αhv)² versus photon energy graphs to extract the optical bandgap); and b) XRD 2θ-ω spectra.

FIG. 12 shows Table 3—summary of Ga₂O₃ phase transformation on hexagonal substrates.

FIG. 13 shows at: a) XRD rocking curves (ω-scan) of (201) β-Ga₂O₃ reflection in samples A2 and B1; b) XRD Φ-scans of {401}-plane of β-Ga₂O₃ and {104}-plane of sapphire for sample B1.

FIG. 14 shows SIMS depth profiles of Al, C, Ga, O, Si elements, CH, and SiOx complexes in: a) sample A2; and b) sample B1.

FIG. 15 shows surface AFM images of the control structure having a thickness of: a) 300 nm (A1) [z scale: 0-37.2 nm]; b) 420 nm (A2) [z scale: 0-70.2 nm]; c) 590 nm (A3) [z scale: 0-83 nm]; and d) sample B1 [z scale: 0-29.5 nm].

FIG. 16 shows at: a) Raman spectra of Ga₂O₃ thin films; b) A_{g}³ g peaks and Gaussian fittings. A_{g}³ g Raman spatial mapping in; c) sample A2; and d) sample B1.

FIG. 17 shows at: a) β-Ga₂O₃ growth direction on a c-plane sapphire or AlN or 6H—SiC assuming a hexagonal structure. Ga₂O₃ on AlN/sapphire template; b) XRD 2θ-ω spectra; c) XRD rocking curves (ω-scan) of (201) β-Ga₂O₃ reflection. d) XRD Φ-scans of {401}-plane of β-Ga₂O₃ and {102}-plane of AlN for sample B2. AFM images of e) sample A4 [z-scale: 0-79.5 nm] and f) sample B2 [z-scale: 0-46.3 nm].

FIG. 18 shows Table 4—The lattice mismatch between β-Ga₂O₃ and hexagonal substrate lattice parameters (LPs) and materials' coefficients of thermal expansion (CTE).

The figures herein are for illustrative purposes only and are not necessarily drawn to scale.

### DETAILED DESCRIPTION OF THE EXAMPLE EMBODIMENTS

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting.

Unless specifically stated, terms and phrases used in this document, and variations thereof, unless otherwise expressly stated, should be construed as open ended as opposed to limiting. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are cited to disclose and describe the methods and/or materials in connection with which the publications are cited. All such publications and patents are herein incorporated by references as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is not also expressly repeated in the instant application should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Where a range is expressed, a further embodiment includes from the one particular value and/or to the other particular value. The recitation of numerical ranges by endpoints includes all numbers and fractions subsumed within the respective ranges, as well as the recited endpoints. Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure. For example, where the stated range includes one or both of the limits, ranges excluding either or both of those included limits are also included in the disclosure, e.g., the phrase “x to y” includes the range from ‘x’ to ‘y’ as well as the range greater than ‘x’ and less than ‘y’. The range can also be expressed as an upper limit, e.g., ‘about x, y, z, or less’ and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the singular forms “a”, “an”, and “the” include both singular and plural referents unless the context clearly dictates otherwise.

As used herein, “about,” “approximately,” “substantially,” and the like, when used in connection with a measurable variable such as a parameter, an amount, a temporal duration, and the like, are meant to encompass variations of and from the specified value including those within experimental error (which can be determined by e.g., given data set, art accepted standard, and/or with e.g., a given confidence interval (e.g., 90%, 95%, or more confidence interval from the mean), such as variations of +/−10% or less, +/−5% or less, +/−1% or less, and +/−0.1% or less of and from the specified value, insofar such variations are appropriate to perform in the disclosure. As used herein, the terms “about,” “approximate,” “at or about,” and “substantially” can mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, “control” can refer to an alternative subject or sample used in an experiment for comparison purpose and included to minimize or distinguish the effect of variables other than an independent variable.

The term “optional” or “optionally” means that the subsequent described event, circumstance or substituent may or may not occur, and that the description includes instances where the event or circumstance occurs and instances where it does not.

The term “molecular weight”, as used herein, can generally refer to the mass or average mass of a material. If a polymer or oligomer, the molecular weight can refer to the relative average chain length or relative chain mass of the bulk polymer. In practice, the molecular weight of polymers and oligomers can be estimated or characterized in various ways including gel permeation chromatography (GPC) or capillary viscometry. GPC molecular weights are reported as the weight-average molecular weight (M_{w}) as opposed to the number-average molecular weight (Mₙ). Capillary viscometry provides estimates of molecular weight as the inherent viscosity determined from a dilute polymer solution using a particular set of concentration, temperature, and solvent conditions.

As used herein, “substantially pure” can mean an object species is the predominant species present (i.e., on a molar basis it is more abundant than any other individual species in the composition), and preferably a substantially purified fraction is a composition wherein the object species comprises about 50 percent of all species present. Generally, a substantially pure composition will comprise more than about 80 percent of all species present in the composition, more preferably more than about 85%, 90%, 95%, and 99%. Most preferably, the object species is purified to essential homogeneity (contaminant species cannot be detected in the composition by conventional detection methods) wherein the composition consists essentially of a single species.

As used interchangeably herein, the terms “sufficient” and “effective,” can refer to an amount (e.g., mass, volume, dosage, concentration, and/or time period) needed to achieve one or more desired and/or stated result(s). For example, a therapeutically effective amount refers to an amount needed to achieve one or more therapeutic effects.

As used herein, “tangible medium of expression” refers to a medium that is physically tangible or accessible and is not a mere abstract thought or an unrecorded spoken word. “Tangible medium of expression” includes, but is not limited to, words on a cellulosic or plastic material, or data stored in a suitable computer readable memory form. The data can be stored on a unit device, such as a flash memory or CD-ROM or on a server that can be accessed by a user via, e.g., a web interface.

As used herein, the terms “weight percent,” “wt %,” and “wt. %,” which can be used interchangeably, indicate the percent by weight of a given component based on the total weight of a composition of which it is a component, unless otherwise specified. That is, unless otherwise specified, all wt % values are based on the total weight of the composition. It should be understood that the sum of wt % values for all components in a disclosed composition or formulation are equal to 100. Alternatively, if the wt % value is based on the total weight of a subset of components in a composition, it should be understood that the sum of wt % values the specified components in the disclosed composition or formulation are equal to 100.

As used herein, “water-soluble”, generally means at least about 10 g of a substance is soluble in 1 L of water, i.e., at neutral pH, at 25° C.

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s). Reference throughout this specification to “one embodiment”, “an embodiment,” “an example embodiment,” means that a particular feature, structure or characteristic described in connection with the embodiment is included in at least one embodiment of the present disclosure. Thus, appearances of the phrases “in one embodiment,” “in an embodiment,” or “an example embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the disclosure. For example, in the appended claims, any of the claimed embodiments can be used in any combination.

All patents, patent applications, published applications, and publications, databases, websites and other published materials cited herein are hereby incorporated by reference to the same extent as though each individual publication, published patent document, or patent application was specifically and individually indicated as being incorporated by reference.

### Kits

Any of the methods/compounds herein can be presented as a combination kit. As used herein, the terms “combination kit” or “kit of parts” refers to the compounds, compositions, formulations and any additional components that are used to package, sell, market, deliver, and/or provide the methods/compounds or a combination of elements or a single element contained therein. Such additional components include, but are not limited to, packaging, blister packages, and the like. When one or more of the methods/compounds, compositions, formulations and any additional components, described herein or a combination thereof contained in the kit are provided simultaneously, the combination kit can contain the methods/compounds in a single combination or in separate combinations. When the compounds, compositions, formulations and any additional components described herein or a combination thereof and/or kit components are not provided simultaneously, the combination kit can contain each methods/compounds in separate combinations. The separate kit components can be contained in a single package or in separate packages within the kit.

In some embodiments, the combination kit also includes instructions printed on or otherwise contained in a tangible medium of expression. The instructions can provide information regarding the content of the compounds and/or methods, safety information regarding the content of the compounds and methods, information regarding the methods/compounds, indications for use, and/or recommended formation regimen(s) for the methods/compounds contained therein. In some embodiments, the instructions can provide directions and protocols for utilizing the methods/compounds described herein such as any of the methods described in greater detail elsewhere herein.

The current disclosure provides thick monoclinic phase-pure gallium oxide (β-Ga₂O₃) layers formed by metal-organic chemical vapor deposition (MOCVD) on c-plane sapphire using silicon-oxygen bonding (SiOₓ) as a phase stabilizer. The β-Ga₂O₃ layers were grown using triethylgallium, oxygen, and silane for gallium, oxygen, and silicon precursors, respectively, at 700° C., with and without incorporating silicon. The samples grown with silicon show a notable reduction in the roughness and resistivity from 10.7 nm to 4.4 nm and from 371.75 Ω-cm to 135.64 Ω-cm. X-ray diffraction reveals a pure-monoclinic phase, and Raman spatial mapping exhibits higher tensile strain in the films in the presence of SiOₓ.

### MOCVD Growths and Thermal Annealing

The Ga₂O₃ epilayers were grown in a low-pressure MOCVD system on c-plane sapphire. Triethylgallium (TEG) and oxygen (O₂) gas were used as gallium and oxygen precursors, and nitrogen (N₂) served as the carrier gas. Multi-parameter growth optimizations were conducted as a function of the temperature (650-820° C.), carrier gas flow, and VI/III ratios. A two-step growth method involving the nucleation layer and the main layer was adopted. The reactor pressure (50 Torr) and substrate temperature (T_{S}=700° C.) were kept constant throughout the growth. For T_{S}>700° C., we observed an early surface roughness build-up. For T_{S}>850° C., the growth rate drops to almost zero after covering the dangling oxygen atoms and deformities of the substrate resulting in a lower thickness caused by the reduction in the sticking coefficient of Ga and O adatoms. See, S. Ghose et al. The CVD growth of Ga₂O₃ at lower temperatures (<700° C.) commonly favors metastable phases, thus not investigated in this work. See, Y. Yao et al. The TEG molar flow rate for the 20 nm buffer/nucleation layer was ˜12 μmol/min, and the VI/III ratio was ˜2340. For the main epilayer, the TEG molar flow rate was ˜29 μmol/min, and the VI/III ratio was ˜940. Silane (SiH₄) was used as the silicon (Si) precursor, and the Si/Ga molar flow ratio was optimized to ˜4×10⁻⁵ for the SiOₓ stabilized Ga₂O₃ samples. For the annealing experiments, the Ga₂O₃ layers were heated to 900-1200° C. for 30 minutes in the same MOCVD reactor, under equal amounts of N₂ and O₂ flows at a pressure of 50 Torr. See C. Y. Huang et al. and J. Lee, et al. The samples were characterized using ultraviolet-visible (UV-Vis) spectroscopy, secondary ion mass spectroscopy (SIMS), high-resolution x-ray diffraction (HR-XRD), Hall effect and mercury probe capacitance-voltage (C-V) measurements, atomic force microscopy (AFM), scanning electron microscopy (SEM), and Raman spectroscopy.

### Results and Discussion

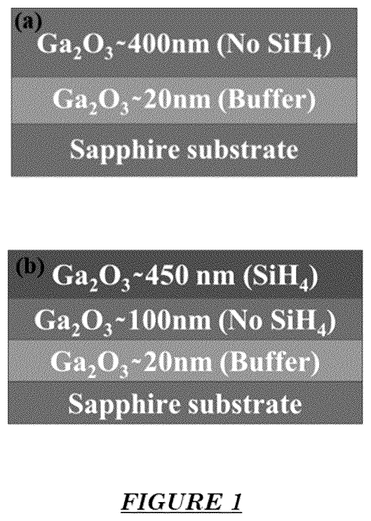

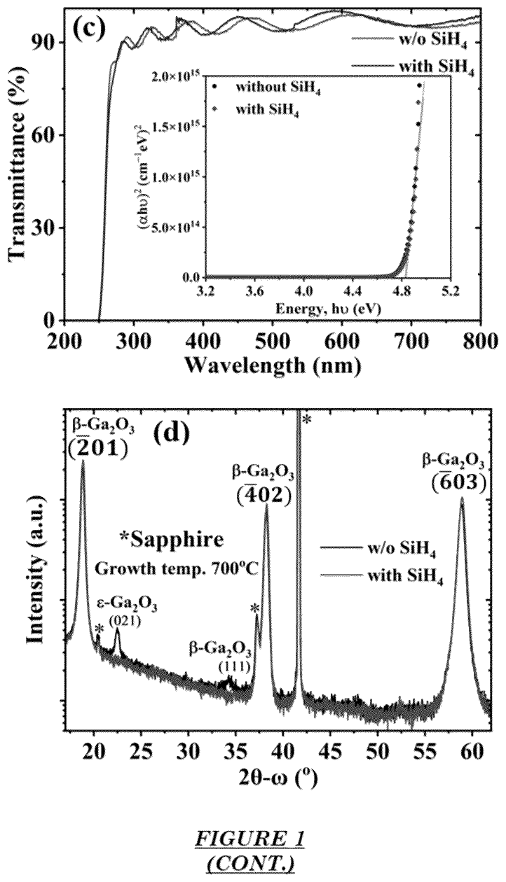

FIG. 1 at a-b shows the schematics of epitaxial structures. A buffer/nucleation layer of ˜20 nm thickness was deposited at 700° C. with a large VI/III ratio to provide a small diffusion length for the gallium atoms creating the nucleation sites. The CVD growth temperature of ˜700° C. is higher than the temperature window for α-Ga₂O₃ vapor phase epitaxy (VPE), see, J. H. Leach et al., and ε-Ga₂O₃ MOCVD growth; see J. Lee et al., thus the nucleation process creates Ga₂O₃ with a higher fraction of 3-phase in the thin film. The epitaxial layer stack in FIG. 1 at a serves as the control structure (sample A) and is also used for annealing experiments. The Ga₂O₃ films of ˜100 nm thickness grown by MOCVD on sapphire show relatively flat surface morphology. See, F. Egyenes-Pörsök. These films are dominated by the β-Ga₂O₃ phase. Thus, to preserve phase purity in Ga₂O₃ films, we introduced SiH₄ gas in the growth process to incorporate silicon after the growth of the first ˜100 nm of the main epitaxial layer, as shown in FIG. 1 at b (sample B).

FIG. 1 at c shows the transmission spectra of both samples which have over 90% transparency with clear Fabri-Perrot fringes in the visible/UV regions and have sharp cutoffs in transmission at ˜258 nm. The thicknesses from transmission data of samples A and B were ˜400 and ˜580 nm, respectively, which were confirmed by measuring sputter crater depth for SIMS. β-Ga₂O₃ is an indirect bandgap semiconductor with only a 30 meV difference between the direct and indirect bandgap. See, K. A. Mengle et al. Therefore, the absorption spectra obey the Tauc and David-Mott relation of direct bandgap material, (αhv)=K(hv−E_{G})^{1/2} where hv, K, α, E_{G} are the photon energy, energy independent constant, absorption coefficient, and bandgap, respectively. The (αhv)² vs. hv plots (FIG. 1 at c inset) exhibit a linear relation in the absorption region, indicating a direct optical bandgap for Ga₂O₃ thin films. Extrapolating the linear absorption region of (αhv)² vs. hv plots to hv=0 yields a bandgap of 4.84 eV for both samples. FIG. 1 at d illustrates the 2θ-ω scans of sample A and B. The 2θ peak positions of Ga₂O₃ and sapphire are indexed using crystallographic information files and reported data from the literature.

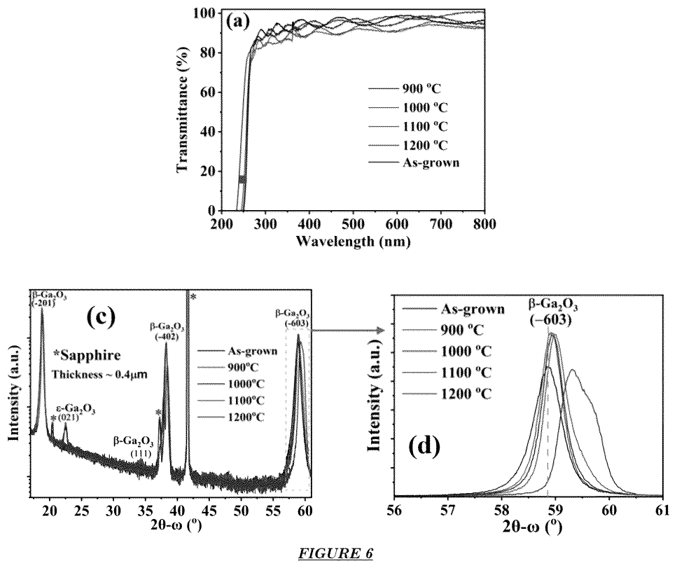

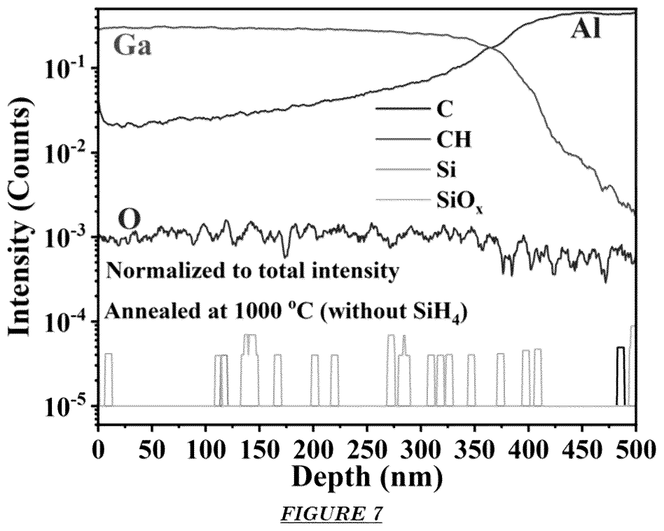

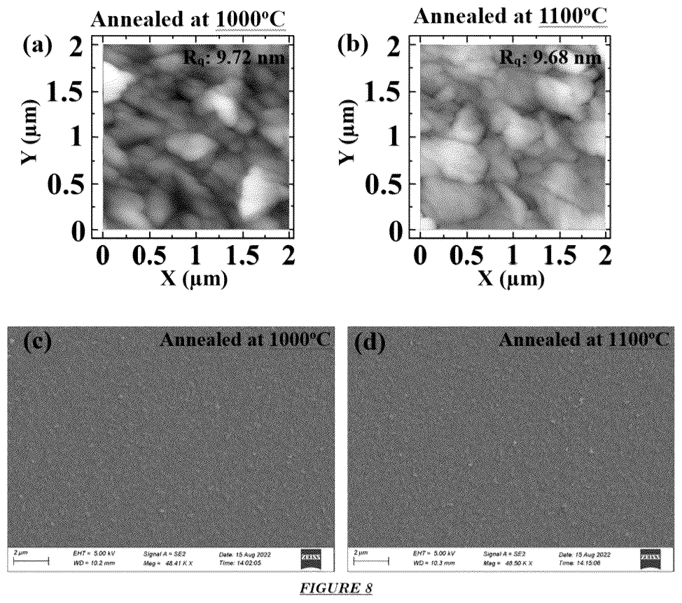

Turning our attention to X-ray diffraction (XRD), the 2θ peaks in the control sample at 18.80°, 38.20°, and 58.85° correspond to (2̅01), (4̅02), and (6̅03) reflections of β-Ga₂O₃. See, S. Ghose et al. and B. R. Tak, M. Garg, S. Dewan, C. G. Torres-Castanedo, K.-H. Li, V. Gupta, X. Li, and R. Singh, J. Appl. Phys. 125, 144501 (2019). The same 2θ peaks red shift by ˜0.05° in sample B. The 2θ peaks at 20.40°, 37.20°, and 41.63° correspond to (003), (404), and (006) reflections of α-Al₂O₃. See, Id. Two additional 2θ peaks in sample A at 22.47° and 34.23° can be indexed as the (021) reflection of ε-Ga₂O₃ and (111) reflection of β-Ga₂O₃. It is rather common to have ε- and β-mixed phases in Ga₂O₃ grown on sapphire using MOCVD at 700° C., see F. Egyenes-Pörsök et al., with increasing thickness these phases grow in a different direction causing an increase in the surface roughness. As seen from FIG. 1 at d, the 2θ peaks at 22.47° and 34.23° are absent when SiH₄ is introduced in the growth process, which gives rise to a ˜580 nm thick (2̅01)-oriented monoclinic phase-pure β-Ga₂O₃. In principle, high-temperature annealing is a simple method to eliminate unwanted phases and obtain a single-phase material. We observed that the thermal annealing at temperature ≥1000° C. eliminates the peaks at 22.47° and 34.23° and produces monoclinic phase-pure thin films. However, the UV transmission spectra show a blue shift in cutoff wavelengths down to 247 nm, and a magnified view shows that the (6̅03) XRD peak shifts to a higher 2θ angle, indicating the transformation of Ga₂O₃ to β-(AlₓGa₁₋ₓ)₂O₃ with annealing. See FIG. 6, which shows at: (a) UV transmittance spectra of annealed Ga₂O₃ thin films, (b) XRD 2θ-ω spectra of the same, and (c) 2θ-ω spectra of (6̅03) peak. On further investigation, the tracing of chemical elements using SIMS measurement as a function of depth shows the presence of Al throughout the ˜400 nm thick Ga₂O₃ film when annealed at 1000° C. See FIG. 7, SIMS profiles of Al, C, Ga, O, Si elements, —CH, and SiOₓ complexes in Ga₂O₃ thin film annealed at 1000° C. for 30 minutes. The Al content (%) can go as high as ˜15% upon annealing, with the diffusion of Al from the sapphire being the source of Al in Ga₂O₃ films. The surface roughness and morphology of the Ga₂O₃ films do not change by thermal annealing. See FIG. 8, Surface AFM image of Ga₂O₃ thin films annealed for 30 minutes at (a) 1000° C., and (b) 1100° C. Top-view SEM images of the same annealed for 30 minutes at (c) 1000° C., and (d) 1100° C. Thus, we conclude that thermal annealing is ineffective in producing thick monoclinic phase-pure β-Ga₂O₃ on sapphire.

The electrical resistivities using the van der Pauw method are measured to be 371.75 Ω·cm in sample A and 135.64 Ω·cm in sample B, demonstrating that the Ga₂O₃ thin films are not electrically highly conductive. Mercury probe capacitance-voltage measurements on both oxide layers also exhibit a moderately resistive nature. Our Si activation annealing did not notably change the conductivity which is consistent with the report by Gogoba et al., see D. Gogova et al., despite Si being a shallow donor in β-Ga₂O₃ with an activation energy of ˜45 meV. See, N. T. Son, K. Goto, K. Nomura, Q. T. Thieu, R. Togashi, H. Murakami, Y. Kumagai, A. Kuramata, M. Higashiwaki, A. Koukitu, S. Yamakoshi, B. Monemar, and E. Janzén, J. Appl. Phys. 120, 235703 (2016). The presence of SiH₄ species in the Ga₂O₃ results in no change in the optical transparency, bandgap, conductivity, and exhibiting 2θ diffraction peaks related only to β-phase and allowing the growth of a thick phase pure (2̅01) β-Ga₂O₃ on sapphire. Such phase stabilization with Si in the form of SiOₓ has also been reported for other binary oxides such as HfO₂. See, T. S. Böscke et al.

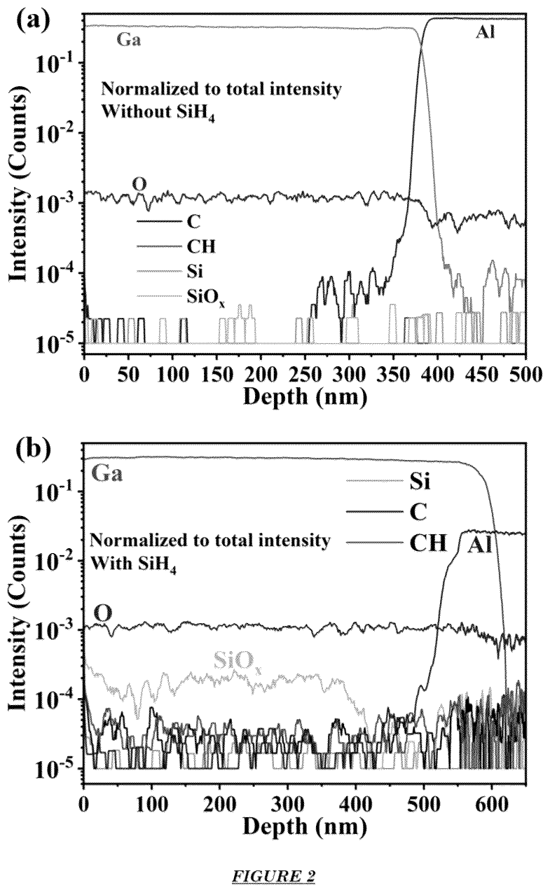

The Time of Flight (TOF) SIMS analysis was used to identify chemical depth profiles of Al, C, Ga, O, Si elements, CH, and SiOₓ, complexes in samples A and B over an area of 500×500 μm² and 600×600 μm² (FIG. 2 at a-b). Bismuth ion (Bi⁺) was used as the primary sputtering ion source. The secondary ions of elements/complexes were detected by mass/charge ratio (m/z) as Al⁺ (m/z 26.9809), C⁺ (m/z 11.9982), Ga⁺ (m/z 68.9259), O⁺ (m/z 15.9932), CH⁺ (m/z 13.0049), and SiOₓ⁻ (m/z 176.9012). See, K. G. Saw and S. R. Esa, Sci. Rep. 11, 7644 (2021). The TEG pyrolysis produces a stable ethylene group, thus, only a low amount of carbon is incorporated in the thin films. See, G. Seryogin et al. However, the MOCVD growth of Ga₂O₃ without carbon contamination requires the combustion of hydrocarbons at high temperatures with sufficient O₂ supply. See, K. Goto, K. Ikenaga, N. Tanaka, M. Ishikawa, H. Machida, and Y. Kumagai, Jpn. J. Appl. Phys. 60, 45505 (2021). The traces of organic compounds through carbon (C) and carbon-hydrogen bonds (CH) were found to be negligible. The Ga and O atoms are uniformly distributed throughout the Ga₂O₃ thickness, and no metal agglomeration is detected. As expected, the Al, Si, and SiOₓ signals also remain at the background level for control Ga₂O₃. A sharp transition from the Ga₂O₃ to the α-Al₂O₃ is observed in both cases. The Si content remains at a low level in sample B. The SIMS analysis confirms the presence of SiOₓ complex in sample B as shown in FIG. 2 at b. Considering the little change in resistivity, the SiOₓ is not an active component of β-Ga₂O₃. Our recent work on point defects of β-Ga₂O₃ using the density functional theory (DFT) suggests that the Si at various charge states have negative defect formation energies, hence, can easily take Ga lattice sites. See, M. Uddin Jewel, S. Hasan, and I. Ahmad, Comput. Mater. Sci. 218, 111950 (2023). Thus, we argue that the Si passivates the gallium vacancies during growth and forms a SiOₓ complex with Si—O bonding being the monoclinic phase stabilizer. This is one of the first reports demonstrating the use of SiOₓ as a phase stabilizer to grow thick phase-pure heteroepitaxial β-Ga₂O₃.

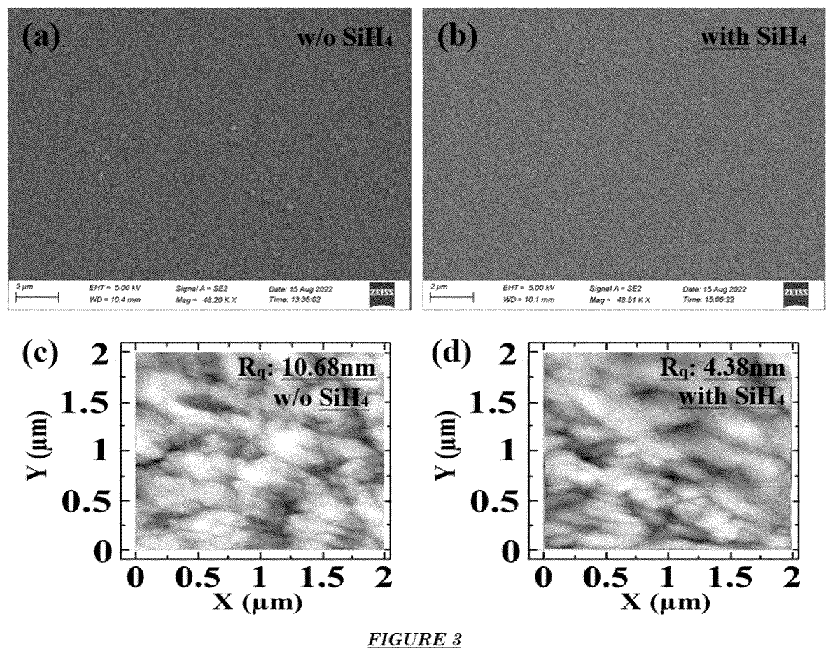

The surface morphologies of Ga₂O₃ films have been characterized by SEM and AFM. Both samples show uniform and continuous morphologies over the entire surface, as illustrated in FIG. 3 at a-b. The AFM images are taken over a 2×2 μm² scan area. The RMS roughness is found to be ˜10.7 nm for sample A, and ˜4.4 nm for sample B, as shown in FIG. 3 at c-d. Both samples show a typical arrangement of β-Ga₂O₃ grains grown on hexagonal substrates. See, X. Xia, Y. Chen, Q. Feng, H. Liang, P. Tao, M. Xu, and G. Du, Appl. Phys. Lett. 108, 202103 (2016). Overall, sample B shows a reduction in RMS roughness by ˜60% and a decrease in the average feature height (h) from h˜41 nm to h˜21 nm as compared to sample A. The Si/Ga molar ratios in Ga₂O₃ layers were explored between ˜10⁻⁴ to 10⁻⁶. For all Si/Ga ratios, the XRD peak related to the mixed-phase completely disappears. However, for lower and higher Si/Ga ratios the surface morphology and roughness remain like that of sample A. For the Si/Ga molar ratio ˜10⁻⁴, the surface deteriorates. At the optimized Ga/Si ratio in Ga₂O₃ layers not only 2θ peaks related to the mixed-phase disappear, but also the surface roughness diminishes.

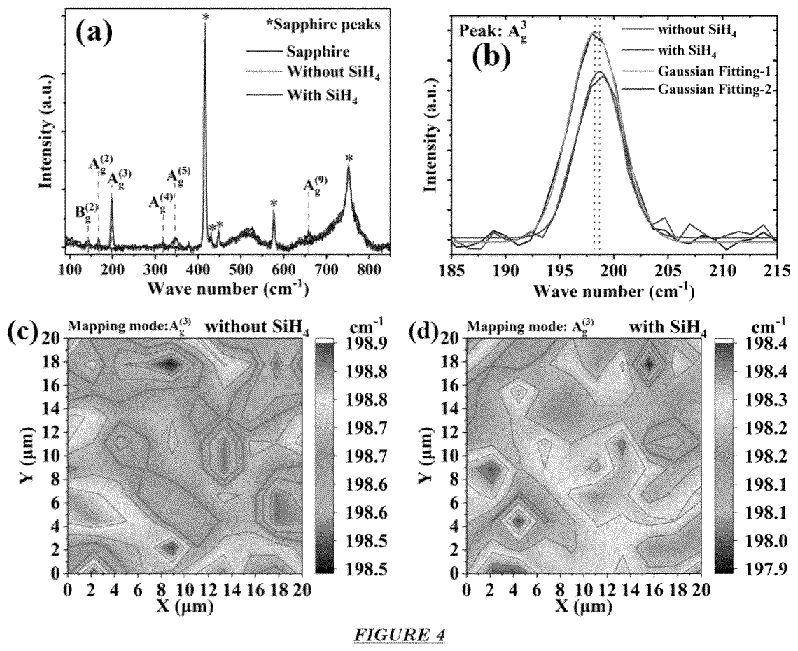

To probe the microstructural homogeneity in the oxide samples, micro-Raman measurements have been performed with 638-nm laser excitation. FIG. 4 at a shows the micro-Raman spectra of the Ga₂O₃ grown without and with SiH₄. The Raman spectrum for c-plane α-Al₂O₃ is taken separately for reference. The peaks denoted with asterisk ‘*’ belong to the sapphire substrate. The Raman spectra of control Ga₂O₃ exhibit phonon modes at 140.81 (B_{g}⁽²⁾), 167.48 (A_{g}⁽²⁾), 198.68 (A_{g}⁽³⁾), 319.71 (A_{g}⁽⁴⁾), 348 (A_{g}⁽⁵⁾), and 658.17 (A_{g}⁽⁹⁾) cm⁻¹ respectively. See, C. Kranert, C. Sturm, R. Schmidt-Grund, and M. Grundmann, Sci. Rep. 6, 1 (2016). The Raman spectrum of β-Ga₂O₃ grown with SiH₄ is identical to the control Ga₂O₃ sample, except for a ˜0.5 cm⁻¹ red-shift, as shown in FIG. 4 at b. For a degenerately Si-doped β-Ga₂O₃ (N_{D}≥3×10¹⁸ cm⁻³), a well-resolved Raman peak appearing at ˜255 cm⁻¹ (D₁) has been reported and attributed to an impurity band caused by Si shallow donors. See, A. Fiedler, M. Ramsteiner, Z. Galazka, and K. Irmscher, Appl. Phys. Lett. 117, 152107 (2020). Hall measurements showed an n-type carrier concentration of ˜1×10¹³ cm⁻³ in sample B. The Si content remains at the background level in sample B as it is below the detection limit (Si˜8×10¹⁶ cm⁻³) for SIMS measurement. See, K. Gogo et al. Neglecting the unintentional doping for the ultrawide bandgap material, and assuming the n-type doping resulting from Si for simplicity, the Si concentration in sample B is ≤10¹³ cm⁻³. We also did not observe any Raman signature related to high silicon doping, substantiating the presence of SiOₓ phase stabilizer in β-Ga₂O₃. The A_{g}⁽³⁾ phonon mode, the intense Raman peak reported in the literature for the bulk (2̅01) β-Ga₂O₃ substrate, see, Y. Song et al. and C. Kranert, is sensitive to residual strain, and the peak position can be anywhere between 195 and 205 cm⁻¹. See, C. Kranert et al. and T. Onuma, S. Fujioka, T. Yamaguchi, Y. Itoh, M. Higashiwaki, K. Sasaki, T. Masui, and T. Honda, J. Cryst. Growth 401, 330 (2014). FIG. 4 at b shows the phonon lines associated with the A_{g}⁽³⁾ peak being positioned at 198.7 and 198.3 cm⁻¹ in sample A and B, respectively. The variation in peak position comes from the difference in strain. The Raman shift can be used to calculate biaxial stress using σ_{B}=−k_{R}^{ph-mode}(ω−ω₀) where k_{R}^{ph-mode} is the Raman biaxial stress conversion factor, ω is the measured phonon frequency, and ω₀ is strain-free phonon frequency at room temperature. See, S. Choi, E. Heller, D. Dorsey, R. Vetury, and S. Graham, J. Appl. Phys. 113, 93510 (2013). The k_{R}^{ph-mode} value is yet to be reported for A_{g}⁽³⁾ phonon mode of β-Ga₂O₃. The ω₀ value is obtained from literature to be ˜199.7 cm⁻¹ for (2̅01) β-Ga₂O₃ substrate. See, Y. Song et al. Because k_{R}^{ph-mode} is a constant, the biaxial strain is directly proportional to frequency shift i.e., ε_{B}∝−(ω−ω₀). A red shift corresponds to tensile strain (ε_{B}>0), whereas a blue shift corresponds to compressive strain (ε_{B}<0). FIG. 4 at c and d show the spatial Raman maps of the A_{g}⁽³⁾ peak for samples A and B. Both samples are structurally homogeneous with the A_{g}⁽³⁾ peak position varying within ˜0.5 cm⁻¹ wave number throughout the spatial map. The average of 100 peaks associated with the A_{g}⁽³⁾ phonon line taken over 20×20 μm² area is ˜198.7 cm⁻¹ for sample A and ˜198.25 cm⁻¹ for sample B. In both cases, the samples show a red shift indicating tensile strain in the epilayers in reference to bulk (2̅01) β-Ga₂O₃, with the tensile strain being higher for the latter case. Thus, the higher Raman shift or strain in the sample with silicon corroborates our observation of ˜0.05° shift in x-ray reflections. The A_{g}⁽³⁾ phonon full-width-half-maximum (FWHM), a measure of the crystalline quality, assessed using a single Gaussian line shape, remains almost the same (˜5 and 5.63 cm⁻¹) in both cases. The FWHM of dominant Raman peak varies between 3 cm⁻¹ for the highest quality bulk crystal to 50 cm⁻¹ for highly defective material. See, V. Lughi and D. R. Clarke, Appl. Phys. Lett. 89, 241911 (2006). The lower FWHM of the dominant peak indicates high quality of thin films. The FWHM of (2̅01) 2θ peaks are ˜0.344 and ˜0.351 for sample A and B, which are comparable to reported values of high quality Ga₂O₃ of similar thicknesses. See, S. Ghose. The FWHMs in conjunction with high optical transparency (>90%) in the visible region ensure the high quality of these heteroepitaxial layers.

The selection of annealing parameters has a significant impact on thermal annealing. Lee et al. reported the formation of cracks in Ga₂O₃ grown on sapphire when annealed at 1000° C. for 30 s under nitrogen (N₂) using rapid thermal annealing (RTA) because of thermal shock. See, J. Lee, H. Kim, L. Gautam, K. He, X. Hu, V. P. Dravid, and M. Razeghi, in Photonics (MDPI, 2021), p. 17. Slower and more precise heating and cooling rate is recommended for the thermal annealing of Ga₂O₃. This supports our reasoning to use an MOCVD reactor for annealing as temperature and gas flows can be precisely controlled. The environment is also crucial for thermal annealing. Huang et al. reported that the nitrogen (N₂) environment is best for thermal annealing in a furnace, see C.-Y. Huang, R.-H. Horng, D.-S. Wuu, L.-W. Tu, and H.-S. Kao, Appl. Phys. Lett. 102, 11119 (2013); contrarily, annealing in an N₂ environment for 30 minutes inside the MOCVD reactor damaged our Ga₂O₃ films due to extended exposure of the material at high temperatures. Annealing in an O₂ environment can diffuse oxygen through the grown Ga₂O₃ and increase the oxygen interstitials (Oᵢ). See, M. N. K. Alam, S. Clima, B. J. O'Sullivan, B. Kaczer, G. Pourtois, M. Heyns, and J. Van Houdt, J. Appl. Phys. 129, 84102 (2021). Gallium interstitials (Gaᵢ), gallium vacancies (V_{Ga}), and oxygen vacancies (V_{O}) also change with annealing due to the breaking of chemical bonds at high temperatures, and oxygen content reaches saturation in an oxygen-excess environment. Therefore, we used N₂/O₂ (50/50%) to partially emulate the air environment (N₂/O₂—78/22%) for thermal annealing.

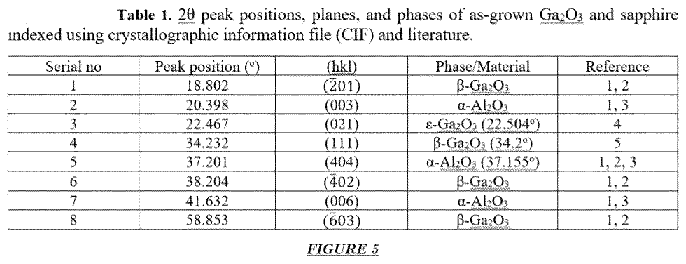

The ˜400 nm thick as-grown Ga₂O₃ samples were annealed at 900-1200° C. for 30 minutes in the MOCVD reactor under N₂/O₂ (1000/1000 sccm) flow; These parameters are typically used for Ga₂O₃ thermal annealing. It is expected that the thermal annealing promotes the recrystallization of Ga₂O₃ and transforms the structures to a stable monoclinic phase (β-phase). However, the UV-transmittance spectra show a blue shift in the optical band transition with annealing, as shown in FIG. 6 at a, indicating the formation of β-(AlₓGa₁₋ₓ)₂O₃. The bandgap shifts from ˜4.84 eV for an as-grown sample to ˜5.04 eV when annealed at 1200° C. Using the bandgap equation E_{G}=4.75+1.87x modeled for β-(AlₓGa₁₋ₓ)₂O₃, see, B. W. Krueger, C. S. Dandeneau, E. M. Nelson, S. T. Dunham, F. S. Ohuchi, and M. A. Olmstead, J. Am. Ceram. Soc. 99, 2467 (2016), the A1-composition can go as high as ˜15% with annealing. The XRD 2θ-ω spectra show that the annealing at 900° C. cannot eliminate the mixed phase, as shown in FIG. 6 at c. Thermal annealing at 1000° C. or higher temperatures produces a monoclinic phase pure thin film in the (201) growth direction. However, the (603) peaks shift to a higher angle in FIG. 6 at d is another indication of increasing Al-content at higher annealing temperatures. See, F. Zhang, K. Saito, T. Tanaka, M. Nishio, M. Arita, and Q. Guo, Appl. Phys. Lett. 105, 162107 (2014). These observations confirm the transformation of Ga₂O₃ to β-(AlₓGa₁₋ₓ)₂O₃ with annealing. FIG. 5 shows Table 1, 20 peak positions, planes, and phases of as-grown Ga₂O₃ and sapphire indexed using crystallographic information file (CIF) and literature.

The SIMS depth profile was also used to identify Al, C, Ga, O, Si elements, SiOₓ, and CH complexes in Ga₂O₃ thin film annealed at 1000° C. for 30 minutes. The 1000° C. is the lowest annealing temperature where the Ga₂O₃ turned into a pure monoclinic phase. The intensities of elements and complexes are normalized to the maximum intensity. The Al, C, Si, SiOₓ, and CH intensities should stay in the background level for pure Ga₂O₃. The depth profile indicates the presence of Al throughout the ˜400 nm thick film of the β-Ga₂O₃ sample annealed at 1000° C. The Al-atoms form sapphire diffused to Ga₂O₃ forming β-(AlₓGa₁₋ₓ)₂O₃ with annealing. The recrystallization by annealing does not change the material thickness. The RMS roughness of annealed samples from AFM measurements remains identical (˜9.7 nm) to as-grown Ga₂O₃, as shown in FIG. 8 at a-b. The average step height from AFM also remains constant (˜41 nm) even after recrystallization. The SEM top surface images of β-(AlₓGa₁₋ₓ)₂O₃ are unaltered and comparable to the as-grown Ga₂O₃ surface.

Even though photodetectors' performance improvements were reported with annealed Ga₂O₃, our extensive analyses and characterizations revealed the limitations of thermal annealing of thick Ga₂O₃. We conclude that thermal annealing is ineffective in producing a thick monoclinic phase-pure β-Ga₂O₃ on sapphire.

The current disclosure provides an alternative use of silicon for β-Ga₂O₃ MOCVD heteroepitaxy as a phase stabilizer in the form of silicon-oxygen (Si—O) bonding. This new approach can offer substantial advantages over thermal annealing for achieving smooth and thick monoclinic phase-pure gallium oxide (β-Ga₂O₃) on sapphire. Our results suggest that thick β-Ga₂O₃ growth reported in this paper should be replicable on thermally conductive hexagonal substrates, such as AlN, 4H—SiC, and 6H—SiC.

The current disclosure provides the growth of monoclinic phase-pure gallium oxide ((3-Ga₂O₃) layers by metal-organic chemical vapor deposition on c-plane sapphire and aluminum nitride (AlN) templates using silicon-oxygen bonding (SiOₓ) as a phase stabilizer. The β-Ga₂O₃ layers are grown using triethylgallium, oxygen, and silane for gallium, oxygen, and silicon precursors, respectively, at 700° C., with and without silane flow in the process. The samples grown on sapphire with SiOₓ phase stabilization show a notable change from samples without phase stabilization in the roughness and resistivity, from 16.2 to 4.2 nm and from 85.82 to 135.64 Ωcm, respectively. X-ray diffraction reveals a pure-monoclinic phase, and Raman spatial mapping exhibits higher tensile strain in the films in the presence of SiO^{x}. The β-Ga₂O₃ layers grown on an AlN template, using the same processes as for sapphire, show an excellent epitaxial relationship between β-Ga₂O₃ and AlN and have a significant change in β-Ga₂O₃ surface morphology.

Different gallium oxide (Ga2O3) phases belong to the wide bandgap semiconductors and have numerous applications. See, G. Seryogin, F. Alema, N. Valente, H. Fu, E. Steinbrunner, A. T. Neal, S. Mou, A. Fine, A. Osinsky, Appl. Phys. Lett. 2020, 117, 262101; S. Ghose, S. Rahman, L. Hong, J. S. Rojas-Ramirez, H. Jin, K. Park, R. Klie, R. Droopad, J. Appl. Phys. 2017, 122, 95302; J. H. Leach, K. Udwary, J. Rumsey, G. Dodson, H. Splawn, K. R. Evans, APL Mater. 2019, 7, 22504; [4] Y. Yao, S. Okur, L. A. M. Lyle, G. S. Tompa, T. Salagaj, N. Sbrockey, R. F. Davis, L. M. Porter, Mater. Res. Lett. 2018, 6, 268; M. Uddin Jewel, S. Hasan, I. Ahmad, Comput. Mater. Sci. 2023, 218, 111950; L. A. M. Lyle, J. Vac. Sci. Technol. A 2022, 40, 60802; N. Makeswaran, A. K. Battu, E. Deemer, C. V. Ramana, Growth Des. 2020, 20, 2893; F. Akyol, I. Demir, Mater. Sci. Semicond. Process. 2022, 146, 106645; and A. K. Singh, M. Gupta, V. Sathe, Y. S. Katharria, Superlattices Microstruct. 2021, 156, 106976.

The monoclinic or β-Ga2O3 phase with a bandgap of ≈4.9 eV, a breakdown field of ≈8MV cm⁻¹, and a Baliga figure-of-merit of 3400, is particularly notable. See, G. Seryogin et al. The growth of monoclinic β-Ga2O3 and their alloys have been reported using different techniques. See, Ghose et al.; M. D. Mia, B. C. Samuels, M. A. A. Talukder, P. D. Borges, L. Scolfaro, W. J. Geerts, R. Droopad, J. Cryst. Growth 2021, 575, 126353; and W. Tang, Y. Ma, X. Zhang, X. Zhou, L. Zhang, X. Zhang, T. Chen, X. Wei, W. Lin, D. H. Mudiyanselage, H. Fu, B. Zhang, Appl. Phys. Lett. 2022, 120, 212103. Two other polymorphs of Ga2O3, namely the corundum (a) and orthorhombic (κ) phases, have bandgap in the 4.4-5.3 eV range. See J. H. Leach et al. and F. Boschi, M. Bosi, T. Berzina, E. Buffagni, C. Ferrari, R. Fornari, J. Cryst. Growth 2016, 443, 25. In κ-Ga2O3, the orthorhombic domains are rotated 1200 against each other, forming a pseudo-hexagonal structure and often called ε-Ga2O3; thus, ε-Ga2O3 and κ-Ga2O3 terms are used interchangeably to refer to orthorhombic Ga2O3 in literature. See, B. M. Janzen, P. Mazzolini, R. Gillen, V. F. S. Peltason, L. P. Grote, J. Maultzsch, R. Fornari, O. Bierwagen, M. R. Wagner, J. Mater. Chem. C 2021, 9, 14175. However, the metastable α- and ε-Ga2O3 phases convert to more stable β-Ga₂O₃ at high temperatures. See, Y. Yao et al.

High-quality homoepitaxial β-Ga2O3 layers and high-performance devices on (010), (001), (100), (201) β-Ga2O3 substrates were demonstrated. See G. Seryogin et al.; W. Tang et al.; S. Sharma, K. Zeng, S. Saha, U. Singisetti, IEEE Electron Device Lett. 2020, 41, 836; R. Schewski, K. Lion, A. Fiedler, C. Wouters, A. Popp, S. V. Levchenko, T. Schulz, M. Schmidbauer, S. Bin Anooz, R. Gruneberg, Z. Galazka; G. Wagner, K. Irmscher, M. Scheffler, C. Draxl, M. Albrecht, APL Mater. 2018, 7, 22515; and B. A. Eisner, P. Ranga, A. Bhattacharyya, S. Krishnamoorthy, M. A. Scarpulla, J. Appl. Phys. 2020, 128, 195703. However, β-Ga2O3 substrates have low thermal conductivity (≈0.27 W cm⁻¹ K), which is not suitable for power semiconductor devices. See, Y. Song, P. Ranga, Y. Zhang, Z. Feng, H.-L. Huang, M. D. Santia, S. C. Badescu, C. U. Gonzalez-Valle, C. Perez, K. Ferri, R. M. Lavelle, D. W. Snyder, B. A. Klein, J. Deitz, A. G. Baca, J.-P. Maria, B. Ramos-Alvarado, J. Hwang, H. Zhao, X. Wang, S. Krishnamoorthy, B. M. Foley, S. Choi, ACS Appl. Mater. Interfaces 2021, 13, 38477. Developing β-Ga2O3 heteroepitaxy on thermally conductive materials like AlN/sapphire template, bulk AlN or 4H—SiC or 6H—SiC substrates can improve heat dissipation in power devices. The β-Ga2O3 grows in the (201) direction as (201) plane of β-Ga2O3 is parallel to the (001) plane of sapphire or AlN or 4H—SiC. For the AlN substrate and AlN/sapphire template, typically ε-Ga2O3 metal-organic chemical vapor deposition (MOCVD) growths were reported. See, Y. Oshima, E. G. Villora, Y. Matsushita, S. Yamamoto, K. Shimamura, J. Appl. Phys. 2015, 118, 85301; A. F. M. A. U. Bhuiyan, Z. Feng, H.-L. Huang, L. Meng, J. Hwang, H. Zhao, J. Vac. Sci. Technol., A 2022, 40, 62704; and W. Chen, Z. Chen, Z. Li, Z. Fei, Y. Pei, G. Wang, Z. He, Appl. Surf. Sci. 2022, 581, 152335. A common method of achieving 0.1-0.7 m thick Ga2O3 on hexagonal substrates is by growing amorphous or α-, β-, ε- (and/or) mixed-phase or mixed-plane Ga2O3 films followed by annealing at temperatures ≥700° C. to create β-Ga2O3. See, C. Y. Huang, R.-H. Horng, D.-S. Wuu, L.-W. Tu, H.-S. Kao, Appl. Phys. Lett. 2013, 102, 11119; and J. Lee, H. Kim, L. Gautam, K. He, X. Hu, V. P. Dravid, and M. Razeghi, Photonics 2021, 8, 17. Extensive studies of the thermal annealing effects on phase transformation in Ga2O3 grown using various deposition processes on sapphire and 4H—SiC substrates have been performed. Thermal annealing of Ga2O3 causes an incomplete phase transformation, see E. Rafie Borujeny, O. Sendetskyi, M. D. Fleischauer, K. C. Cadien, ACS Appl. Mater. Interfaces 2020, 12, 44225, mixed phases, see Y. Meng, Y. Gao, K. Chen, J. Lu, F. Xian, L. Xu, G. Zheng, W. Kuang, Z. Cao, Optik 2021, 244, 167515, mixed planes of β-phase, see J. Yu, Z. Nie, L. Dong, L. Yuan, D. Li, Y. Huang, L. Zhang, Y. Zhang, R. Jia, J. Alloys Compd. 2019, 798, 458, thin films cracking, see C. Wang, S.-W. Li, Y.-C. Zhang, W.-H. Fan, H.-J. Lin, D.-S. Wuu, S.-Y. Lien, W.-Z. Zhu, Vacuum 2022, 202, 111176, and atomic diffusion from substrates as discussed in the supporting information. As a result, thermal annealing is not a suitable option for achieving phase pure β-Ga2O3 grown on hexagonal materials. Binary oxides (Hafnia HfO2, Zirconia ZrO2) have been phase stabilized by incorporating foreign elements (e.g., Si, Y, Mg). Tomida et al. were able to stabilize cubic phase HfO2 instead of monoclinic/cubic mixed phase HfO2 by introducing silicon and forming silicon-oxygen bonding (SiOₓ), which was referred as hafnium-silicate (Hf1 xSixO2). See, K. Tomida, K. Kita, A. Toriumi, Appl. Phys. Lett. 2006, 89, 142902. The dielectric constant (εr) increased slightly as a result of phase stabilization. The cubic phase of ZrO2 can be stabilized with yttrium and forming yttria (Y2O3) as a second material phase, commonly known as yttria-stabilized zirconia. See, P. Duwez, F. H. Brown, F. Odell, J. Electrochem. Soc. 1951, 98, 356.

Herein, the current disclosure provides the MOCVD growth of phase-pure β-Ga2O3 on c-plane sapphire and AlN templates by introducing silicon-oxygen (Si—O) bonding in the lattice structure. A ≈580 nm layer of β-Ga2O3 with silane was grown on a sapphire substrate and compared with as-grown and thermally annealed Ga2O3 films grown without silane. The current disclosure also demonstrated phase-pure, smooth (201) β-Ga2O3 on AlN/sapphire template with silane flow in the process significantly changing surface morphology.

### MOCVD Growths and Thermal Annealing

### Ga2O3 Growth on Sapphire

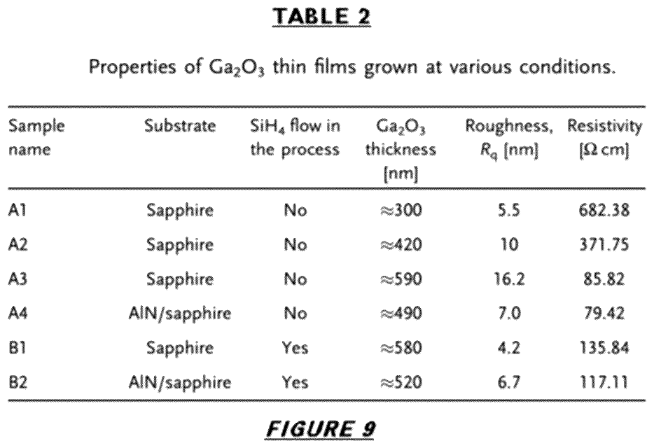

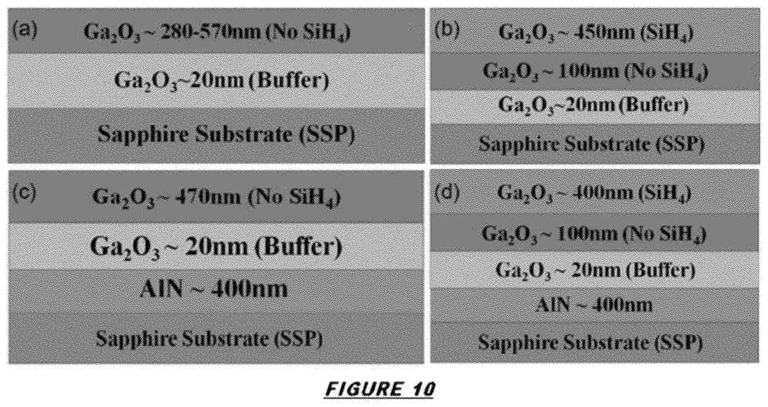

The Ga2O3 epilayers were grown in a low-pressure MOCVD system on c-plane sapphire with 0.2° miscut. Triethylgallium (TEG) and oxygen (02) gas were used as gallium and oxygen precursors, and nitrogen (N2) served as the carrier gas. Multiparameter growth optimizations were conducted as a function of the temperature (650-820° C.), carrier gas flow, and VI/III ratios. A two-step growth method involving the nucleation layer and the main layer was adopted. The reactor pressure (50 Torr) and substrate temperature (TS=700° C.) were kept constant throughout the growth. For TS>700° C., we observed an early surface roughness build-up. For TS>850° C., the growth rate drops to almost zero after covering the dangling oxygen atoms and deformities of the substrate resulting in a lower thickness caused by the reduction in the sticking coefficient of Ga and O adatoms. See, S. Ghose et al. The CVD growth of Ga2O3 at lower temperatures (<700° C.) commonly favors metastable phases, thus not investigated in this disclosure. See, Y. Yao et al. The TEG molar flow rate for the 20 nm buffer/nucleation layer was ≈12 μmol min⁻¹, and the VI/III ratio was ≈2340. For the main epilayer, the TEG molar flow rate was ≈29 μmol min⁻¹, and the VI/III ratio was ≈940. Silane (SiH4) was used as the silicon (Si) precursor, and the Si/Ga molar flow ratio was optimized to ≈4×10⁻⁵ for the SiOx stabilized Ga2O3 samples. All the samples grown without SiH4 flow belong to the “A” series and the samples grown with SiH4 belong to the “B” series. Table 2, see FIG. 9, shows the characteristics of the samples used in this disclosure. FIG. 9 shows Table 2—properties of Ga₂O₃ thin films grown at various conditions. The samples without SiH4; A1, A2, A3, and A4 are used as the control structures. The schematic of the layer structure of the samples used in this disclosure is shown in FIG. 10. FIG. 10 shows FIG. 10 shows a schematic of Ga₂O₃ epilayers on sapphire: a) without SiH₄ (sample A1, A2, A3); b) with SiH₄ (sample B1), and on AlN/sapphire templates; c) without SiH4 (sample A4); and d) with SiH₄ (sample B2). Both “A” and “B” sample series were initially grown in a similar way. First, a 20 nm Ga2O3 buffer layer was grown, and then up to 100 nm Ga2O3 main epilayer was grown. We kept growing the same way for the control structures (A1, A2, A3) to achieve different thicknesses. But in sample B1 after 100 nm, we grew 450 nm thick Ga2O3 with silane at different Si/Ga molar flow ratios. These layer structures are shown in FIG. 10 at a and b.

### Thermal Annealing and Stability of Ga2O3/Sapphire

A slower and more precise heating and cooling rate is recommended for the thermal annealing of Ga2O3. The Ga2O3 sample A2 was annealed at 900-1200° C. for 30 min in the same MOCVD reactor in which it was grown under equal amounts of N2 and O2 flows (1000 sccm) at a pressure of 50 Torr in a similar way described in the literature. See, C. Y. Huang et al, J. Lee et al., and X. Zhou, Y. Ma, G. Xu, Q. Liu, J. Liu, Q. He, X. Zhao, S. Long, Appl. Phys. Lett. 2022, 121, 223501.

### Ga2O3 Growth on AlN/Sapphire

To study the growth of Ga2O3 on AlN/sapphire templates, 0.4 m thick AlN layers were grown in the MOCVD reactor on a 0.2° miscut c-plane sapphire using N2 carrier gas at 50 Torr reactor pressure. Trimethylaluminum (TMA) and ammonia (NH3) were used as aluminum (A1) and nitrogen precursors. The growth starts with the nitridation of sapphire substrate for 15 min at a temperature of 1,120° C. A pulsed mode growth of 100 nm AlN buffer layer at 990° C. was carried out by turning NH3 on/off for 6/12 s while maintaining continuous TMA flow with an average V/III ratio of ≈3900. The AlN buffer layer provides a rough 3D surface for stain reduction for subsequent thick AlN. For the 0.3 m thick main epilayer, the temperature is increased to 1230° C. with continuous NH3 flow to maintain a V/III ratio of ≈975. The growth rate of AlN is 0.75 μm h-1. We have previously reported a detailed growth process of AlN on sapphire elsewhere. See, S. Hasan, A. Mamun, K. Hussain, M. Gaevski, I. Ahmad, A. Khan, J. Mater. Res. 2021, 36, 4360; and S. Hasan, M. U. Jewel, S. G. Karakalos, M. Gaevski, I. Ahmad, Coatings 2022, 12, 924.

The schematics of the Ga2O3 epilayer on AlN/sapphire templates are shown in FIG. 10 at c and d. These samples (A4 and B1) are grown without and with SiH4 using the same processes as explained for sapphire substrates.

### Ga2O3 Growth on Sapphire

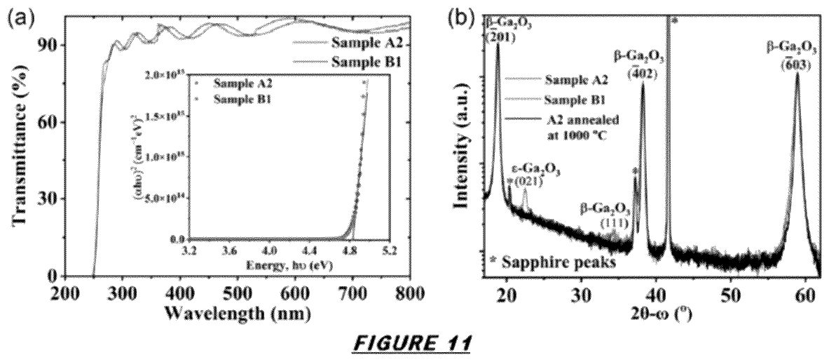

FIG. 11 at a, shows the transmission spectra of samples A2 and B1; both have over 90% transparency with clear Fabri-Perrot fringes in the visible UV regions and have sharp cutoffs in transmission at ≈258 nm. FIG. 11 shows Ga₂O₃ thin films: a) UV transmittance spectra (inset shows the (αhv)² versus photon energy graphs to extract the optical bandgap); and b) XRD 2θ-ω spectra. The thicknesses from transmission data of samples A2 and B1 were ≈420 and ≈580 nm, respectively, which were verified by measuring sputter crater depth for secondary ion mass spectroscopy (SIMS). We are comparing the properties of samples A2 and B1 as the thickness of the epilayer in sample B1 grown with silane is ≈450 nm which is closer to the sample A2 thickness (≈420 nm). The results of thermal annealing are also based on sample A2. β-Ga2O3 is an indirect bandgap semiconductor with only a 30 meV difference between the direct and indirect bandgap. See, K. A. Mengle, G. Shi, D. Bayerl, E. Kioupakis, Appl. Phys. Lett. 2016, 109, 212104.

Therefore, the absorption spectra obey the Tauc and David-Mott relation of direct bandgap material, (αhv)=K(hv−E_{G})^{1/7}, where hv, K, α, EG are the photon energy, energy independent constant, absorption coefficient, and bandgap, respectively. The (αhv)² versus hv plots in FIG. 11 at a exhibits a linear relation in the absorption region, indicating a direct optical bandgap for Ga2O3 thin films. Extrapolating the linear absorption region of (αhv)² versus hv plots to hv=0 yields a bandgap of 4.84 eV for both samples A2 and B1. FIG. 11 at b illustrates the 2θ-ω scans of samples A2 and B1. The 2θ peak positions of Ga2O3 and sapphire are indexed using crystallographic information files (CIFs) and reported data from the literature. See, J. H. Leach et al. and B. R. Tak, M. Garg, S. Dewan, C. G. Torres-Castanedo, K.-H. Li, V. Gupta, X. Li, R. Singh, J. Appl. Phys. 2019, 125, 144501.

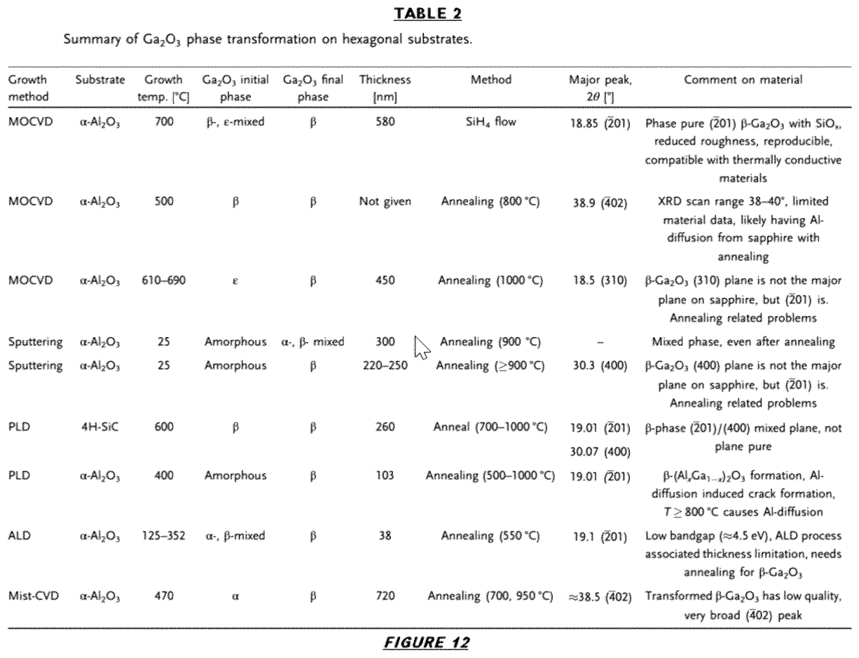

Turning our attention to X-ray diffraction (XRD), the 2θ peaks in the control sample A2 at 18.80°, 38.20°, and 58.85° correspond to (201), (402) and (603) reflections of β-Ga₂O₃. See Id. The same 2θ peaks red shift by ≈0.05° in sample B1. The 2θ peaks at 20.40°, 37.20°, and 41.63° correspond to (003), (404), and (006) reflections of sapphire (α-Al₂O₃). See Id. Two additional 2θ peaks in sample A2 at 22.470 and 34.230 can be indexed as the (021) reflection of ε-Ga2O3 and (111) reflection of β-Ga2O3. We used the CIF files mp-886 for β-Ga2O3 and mp-13 134 for ε-Ga2O3 from materials project (mp) to index unknown 2θ reflections. It is common to have ε- and β-mixed phases in Ga2O3 grown on sapphire using MOCVD at 700° C., see F. Egyenes-Pörsök, F. Gucmann, K. Hušeková, E. Dobroÿ cka, M. Sobota, M. Mikolášek, K. Fröhlich, M. Ťapajna, Semicond. Sci. Technol. 2020, 35, 115002, with increasing thickness; these phases grow in different directions, causing an increase in the surface roughness. As seen from FIG. 11 at b, the 2θ peaks at 22.470 and 34.23° are absent when SiH4 is introduced in the growth process, which gives rise to a ≈580 nm thick (201)-oriented monoclinic phase-pure β-Ga2O3. In principle, high-temperature annealing is a simple method to eliminate unwanted phases and obtain a single-phase material. We observed that the thermal annealing at a temperature ≥1000° C. eliminates the peaks at 22.47° and 34.23° and produces monoclinic phase-pure thin films. However, the UV transmission spectra show a blue shift in cutoff wavelengths down to 247 nm, and a magnified view shows that the (603) XRD peak shifts to a higher 2θ angle, indicating the transformation of Ga2O3 to β-(AlxGa1 x)2O3 with annealing. On further investigation, the tracing of chemical elements using SIMS measurement as a function of depth shows the presence of A1 throughout the 420 nm Ga₂O₃ film when annealed at 1000° C. The A1 content (%) can go as high as 15% with annealing, with the diffusion of A1 from the sapphire being the source of A1 in Ga₂O₃ films. The surface roughness and morphology of the Ga₂O₃ films do not change by thermal annealing. The thermal annealing of Ga₂O₃ on hexagonal substrates produces the mixed phase, the mixed plane of β-phase, low-quality material, and cracked β-(Al1 xGax)2O3 due to A1-diffusion and sample/substrate thermal mismatch as summarized Table 3, see FIG. 12. FIG. 12 shows Table 3—summary of Ga₂O₃ phase transformation on hexagonal substrates. Based on our data and the reports in Table 3, we conclude that thermal annealing is ineffective in producing a monoclinic phase and plane pure β-Ga₂O₃ on sapphire.

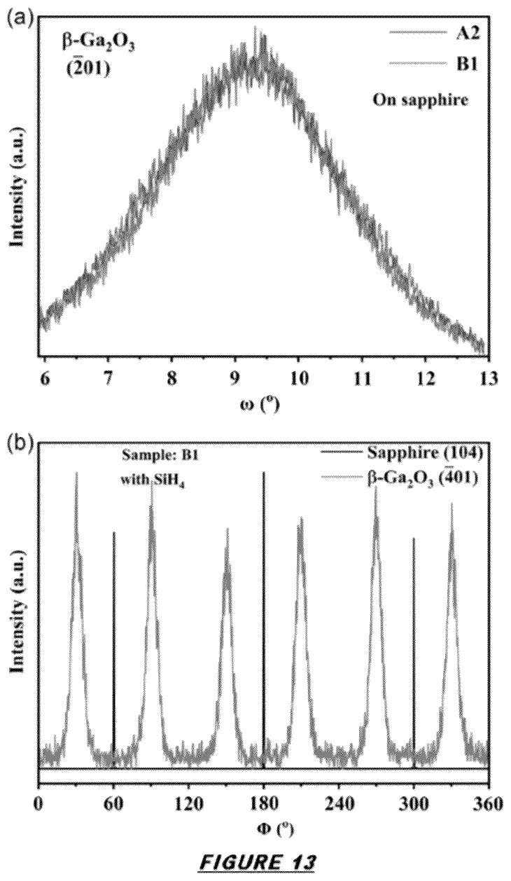

The (201) ω-rocking curves (RCs) are used to evaluate the crystalline quality of β-Ga₂O₃. The Ga₂O₃ shows a 3D columnar growth mode or β-Ga₂O₃ grains on c-plane sapphire. See, X. Xia, Y. Chen, Q. Feng, H. Liang, P. Tao, M. Xu, G. Du, Appl. Phys. Lett. 2016, 108, 202103; and M.-Y. Tsai, O. Bierwagen, M. E. White, J. S. Speck, J. Vac. Sci. Technol. A 2010, 28, 354. This causes a limited diffusion length of adatoms, many twins, and stacking faults in the (201) growth direction. See, W. Tang et al. and B. A. Eisner et al. This problem also persists in (201) β-Ga2O3 homoepitaxy. See B. A. Eisner et al. A broad (201) RC is expected in the growth direction due to many defects and misoriented structures. Rafique et al. reported the full width at half maximum (FWHM) from (201) ω-RC of 1.49° for a 3.42 μm thick β-Ga2O3 on sapphire grown by LPCVD. See, S. Rafique, L. Han, A. T. Neal, S. Mou, M. J. Tadjer, R. H. French, H. Zhao, Appl. Phys. Lett. 2016, 109, 132103. FIG. 13 at a shows the (201) ω-scans of samples A2 and B1. FIG. 13 shows at: a) XRD rocking curves (ω-scan) of (201) β-Ga₂O₃ reflection in samples A2 and B1; b) XRD Φ-scans of {401}-plane of β-Ga₂O₃ and {104}-plane of sapphire for sample B1. The (201) ω-peaks were found at 9.2° in sample A2 and at 9.120 in sample B1. The FWHMs of (201) ω-RCs are 3.26° (A2), and 3.57° (B1). The FWHMs slightly increase with SiH4 flow. The in-plane rotational domain properties of β-Ga2O3 on sapphire were examined by XRD Φ-scans on sample B1, as shown in FIG. 13 at b. Three {104}-plane peaks separated by 1200 show the trigonal space symmetry of sapphire (α-Al2O3). Six β-Ga2O3 {401}-plane strong peaks with similar intensities were measured in both samples A2 and B1. The 600 apart six {401}-plane peaks indicate the presence of sixfold in-plane rotational symmetry in β-Ga2O3 thin films. However, the β-Ga2O3 {401}-planes have two-fold in-plane rotational symmetry on sapphire as there are three equivalent in-plane orientations of β-Ga2O3 on sapphire. The twofold β-Ga2O3 films grew epitaxially in the three different directions at the same rates, causing six {401}-plane peaks or sixfold rotational symmetry on sapphire. See, S. Ghose et al. The XRD Φ-scans on sample A2 show similar properties.

The electrical resistivities are measured using the van der Pauw method. The resistivity decreases with the thickness from 682.38 Ωcm (A1) to 85.82 Ωcm (A3) as the thickness of the control structure increases from 300 nm (A1) to 590 nm (A3). Comparing the resistivities of the samples with similar thicknesses grown on sapphire with and without SiH4 flow, i.e., sample A3 and B1, we observed that resistivity increased from 85.82 to 135.84 Ωcm, which demonstrates that the silicon atoms in Ga2O3 thin films are not changing the n-type dopant concentration. Both samples (A3 and B1) were moderately resistive with a difference in the electrical resistivities of ≈50 Ωcm or ≈37%. The Si activation annealing did not notably change the conductivity, which is consistent with the report by Gogova et al., see D. Gogova, G. Wagner, M. Baldini, M. Schmidbauer, K. Irmscher, R. Schewski, Z. Galazka, M. Albrecht, R. Fornari, J. Cryst. Growth 2014, 401, 665, despite Si being a shallow donor in β-Ga₂O₃ with an activation energy of ≈36-45 meV. See, N. T. Son, K. Goto, K. Nomura, Q. T. Thieu, R. Togashi, H. Murakami, Y. Kumagai, A. Kuramata, M. Higashiwaki, A. Koukitu, S. Yamakoshi, B. Monemar, E. Janzén, J. Appl. Phys. 2016, 120, 235703; and X. Xiang, L.-H. Li, C. Chen, G. Xu, F. Liang, P. Tan, X. Zhou, W. Hao, X. Zhao, H. Sun, K.-H. Xue, N. Gao, S. Long, Sci. China Mater. 2023, 66, 748. The introduction of SiH4 in the Ga2O3 growth results in no observed change in the material bandgap, maintaining high resistivity, and exhibiting 2θ diffraction peaks related only to β-phase and allowing the growth of a phase pure (201) β-Ga2O3 on sapphire. Such phase stabilization with Si in the form of SiOₓ has been reported for other binary oxides like HfO2. See, K. Tomida et al.

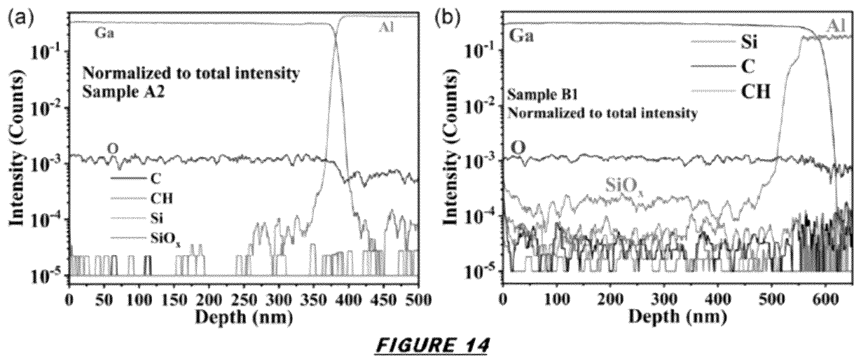

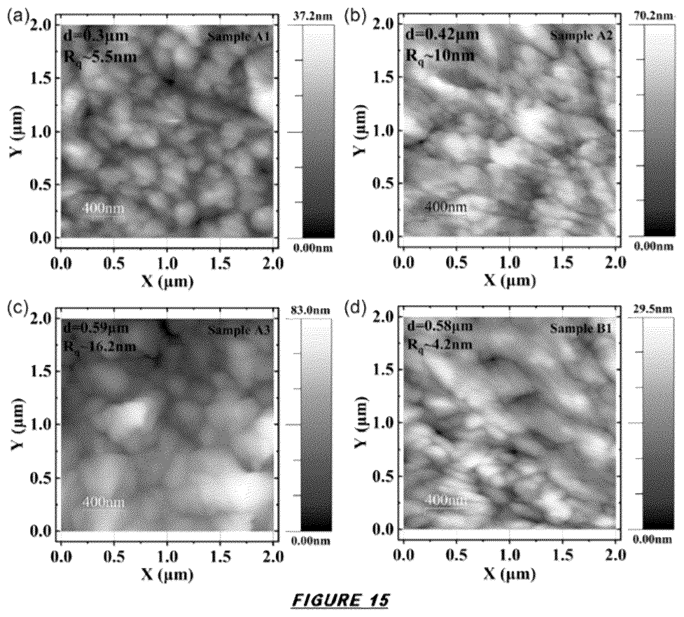

To further investigate the role of silane flow during Ga2O3 growth, we performed SIMS analysis. FIG. 14 provides the time-of-flight (TOF) SIMS analysis used to identify chemical depth profiles of Al, C, Ga, O, Si elements, CH, and SiOx, complexes in samples A2 and B1. FIG. 14 shows SIMS depth profiles of Al, C, Ga, O, Si elements, CH, and SiOx complexes in: a) sample A2; and b) sample B1. The secondary ions of elements/complexes were detected by mass/charge ratio (m/z) as Al⁺ (m/z 26.9809), C⁺ (m/z 11.9982), Ga⁺ (m/z 68.9259), O⁺ (m/z 15.9932), CH⁺ (m/z 13.0049), and SiOx (m/z 176.9012). See, K. G. Saw, S. R. Esa, Sci. Rep. 2021, 11, 7644. The TEG pyrolysis produces a stable ethylene group; thus, only a low amount of carbon is incorporated in the thin films. See, Seryogin et al. However, the MOCVD growth of Ga2O3 without carbon contamination requires the combustion of hydrocarbons at high temperatures with sufficient O2 supply. See, K. Goto, K. Ikenaga, N. Tanaka, M. Ishikawa, H. Machida, Y. Kumagai, Jpn. J. Appl. Phys. 2021, 60, 45505. The traces of organic compounds through carbon (C) and carbon-hydrogen bonds (CH) were found to be negligible. The Ga and O atoms are uniformly distributed throughout the Ga2O3 thickness, and no metal agglomeration is detected. As expected, the Al, Si, and SiOx signals also remain at the background level for control Ga2O3 (sample A2), as shown in FIG. 14 at a. A sharp transition from the Ga2O3 to the α-Al2O3 is observed in both cases. The Si content remains at a low level in the sample grown without silane (sample A2). The SIMS analysis confirms the presence of SiOx complex in the sample grown with silane (sample B1), as shown FIG. 14 at b. Considering the increase in the resistivity (85.82 Ωcm in 590 nm thick sample (A3) to 135.84 Ωcm in 580 nm thick sample (B1)) further solidifies that the SiOₓ is not acting as a donor in β-Ga2O3. Hall measurements showed an n-type carrier concentration of ≈1×10⁻¹³ cm⁻³ in sample B1. The reported Si detection limit is ≈8×10¹⁶ cm⁻¹ in β-Ga₂O₃ for SIMS measurement. See Id. Neglecting the unintentional doping for the ultrawide bandgap material and assuming the n-type doping resulting from Si for simplicity, the Si-dopant concentration in sample B is ≤10¹³ cm⁻³. The Si-dopant concentration in β-Ga2O3 was low (Si≤10¹³ cm⁻³), and silicon activation annealing resulted in a negligible change in the conductivity. Such phenomena of β-Ga2O3 on sapphire with SiH4 gas were analyzed by Gogova et al. One of the reasons was attributed to the formation of SiOₓ as a second phase in the β-Ga2O3 as Si has a strong affinity to oxygen. See Id. Rafique et al. later reported the SiOx formation in β-Ga2O3 caused due the compensation of Si by gallium vacancies (VGa). See, S. Rafique et al. Considering SiOx as a second phase in β-Ga2O3, we traced the SiO x (m/z 59.9696) and GaO⁻ (m/z 84.9214) throughout the sample B1. The ratio of the average intensity counts for SiOx and GaO⁻ is ≈0.13%. We believe this trace amount of SiOₓ was not sufficient to significantly impact the crystal structure of β-Ga2O3. We argue that the Si passivates the gallium vacancies (VGa) during growth, taking Ga-lattice sites, and forming a SiOₓ complex in β-Ga₂O₃. Therefore, we conclude that (201) β-Ga2O3 phase stabilization is obtained by forming trace amount of SiOₓ. This is one of the first reports demonstrating the use of SiOₓ as a phase stabilizer to grow phase-pure heteroepitaxial β-Ga2O3. The surface morphologies of Ga2O3 films have been characterized by scanning electron microscopy (SEM) and atomic force microscopy (AFM). Both samples A2 and B1 show uniform and continuous morphologies over the entire surface. The AFM images are taken over a 2×2 μm² scan area. As the Ga2O3, employing the growth process of the “A” series, becomes thicker than ≈250 nm on c-plane sapphire, the surface roughness starts building up, as shown in FIG. 15 at a-c where the thickness is increased from 300 nm (A1) to 590 nm (A3), correspondingly root mean square (RMS) roughness increases from 5.5 to 16.2 nm. FIG. 15 shows surface AFM images of the control structure having a thickness of: a) 300 nm (A1) [z scale: 0-37.2 nm]; b) 420 nm (A2) [z scale: 0-70.2 nm]; c) 590 nm (A3) [z scale: 0-83 nm]; and d) sample B1 [z scale: 0-29.5 nm]. The RMS roughness is found to be ≈10.0 nm for sample A2 (≈420 nm thick) and ≈4.2 nm for sample B1 shown in FIG. 15 at d. These A1, A2, A3, and B1 samples show a 3D columnar growth mode or β-Ga2O3 grains on sapphire. See, X. Xia et al. and M. Y. Tsai et al. Overall, sample B1 shows a reduction in RMS roughness by ≈60% compared to sample A2, and ≈₇₅% compared to the ≈590 nm thick sample A3. The decrease in the average feature height (h) in sample B1 from h≈ 41 nm to h≈ 21 nm as compared to sample A2 and h≈ 61 nm to h≈ 21 nm as compared to sample A3 are observed. The reduction in the roughness in sample B1 is due to silane flow in the process, as confirmed by SIMS; like the foreign elements in the growth process as reported for binary oxides (HfO2, ZrO2) and III-nitrides (GaN, Al1 xGaxN). See, K. Tomida et al., P. Duwez et al, and K. S. Qwah, E. Farzana, A. Wissel, M. Monavarian, T. Mates, J. S. Speck, APL Mater. 2022, 10, 81107. The Si/Ga molar ratios in Ga2O3 layers were explored between ≈10⁻⁴ and ≈10⁻⁶. For all Si/Ga ratios, the XRD peaks related to the mixed phase completely disappear. However, for lower and higher Si/Ga ratios, the surface morphology and roughness remain like that of sample A2. For the Si/Ga molar ratio ≈10⁻⁴, the surface deteriorates. At the optimized Ga/Si ratio in Ga2O3 layers, not only 2θ peaks related to the mixed-phase disappear, but also the surface roughness diminishes.

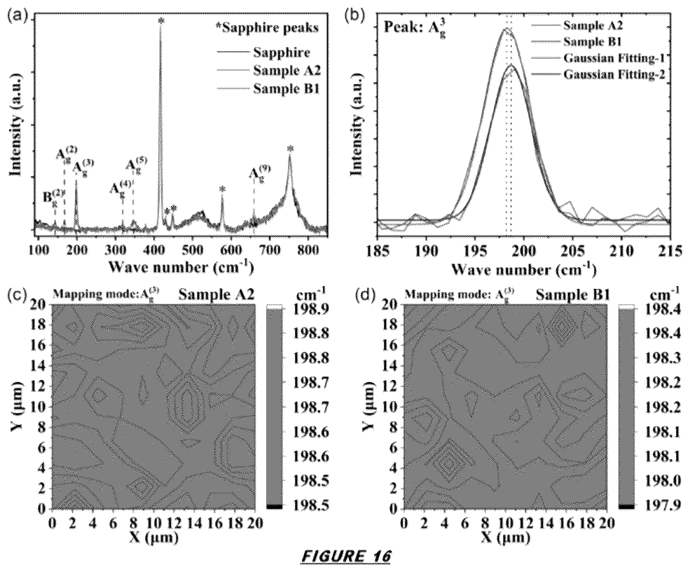

Micro-Raman measurements have been performed to probe the microstructural homogeneity in Ga2O3 layers. FIG. 16 at a provides the micro-Raman spectra of the Ga2O3 samples A2 and B1. FIG. 16 shows at: a) Raman spectra of Ga₂O₃ thin films; b) A_{g}³ g peaks and Gaussian fittings. A_{g}³ g Raman spatial mapping in; c) sample A2; and d) sample B1. The Raman spectrum for c-plane sapphire (α-Al2O3) is taken separately for reference. The peaks denoted with an asterisk “*” belong to the sapphire substrate. The Raman spectra of Ga2O3 sample A2 exhibit phonon modes at 140.81 (B_{g}⁽²⁾), 167.48 (A_{g}⁽²⁾), 198.68 (A_{g}⁽³⁾), 319.71 (A_{g}⁽⁴⁾), 348 (A_{g}⁽⁵⁾), and 658.17 (A_{g}⁽⁹⁾) cm⁻¹ respectively. C. Kranert, C. Sturm, R. Schmidt-Grund, M. Grundmann, Sci. Rep. 2016, 6, article no. 35964. The Raman spectrum of β-Ga2O3 grown with SiH4 (sample B1) is identical to the control Ga2O3 sample, except for a ≈0.50 cm⁻¹ red-shift, as shown in FIG. 16 at b. For a degenerately Si-doped β-Ga2O3 (ND≥3×10¹⁸ cm⁻³), a well resolved Raman peak appearing at ≈255 cm⁻¹ (D1) has been reported and attributed to an impurity band caused by Si shallow donors. See A. Fiedler, M. Ramsteiner, Z. Galazka, K. Irmscher, Appl. Phys. Lett. 2020, 117, 152107. We did not observe any Raman signature related to high silicon doping, further substantiating the presence of SiOₓ phase stabilizer in β-Ga2O3. The A_{g}⁽³⁾ phonon mode, the intense Raman peak reported in the literature for the bulk (201) β-Ga2O3 substrate, see Y. Song et al. and C. Kranet et al. is sensitive to residual strain, and the peak position can be anywhere between 195 and 205 cm-1. See, C. Kranert et al. and T. Onuma, S. Fujioka, T. Yamaguchi, Y. Itoh, M. Higashiwaki, K. Sasaki, T. Masui, T. Honda, J. Cryst. Growth 2014, 401, 330. FIG. 16 at b shows the phonon lines associated with the A_{g}⁽³⁾ peak being positioned at 198.70 and 198.30 cm⁻¹ in sample A2 and B1, respectively. The variation in peak position comes from the difference in strain. The Raman shift can be used to calculate biaxial stress using σB=−k_{R}^{ph-mode}(ω−ω₀), where k_{R}^{ph-mode} is the Raman biaxial stress conversion factor, ω is the measured phonon frequency, and ω0 is the strain-free phonon frequency at room temperature. See, S. Choi, E. Heller, D. Dorsey, R. Vetury, S. Graham, J. Appl. Phys. 2013, 113, 93510. The k_{R}^{ph-mode} value is yet to be reported for A phonon mode of β-Ga2O3. The ω0 value is obtained from literature to be 199.70 cm⁻¹ for (201) β-Ga2O3 substrate. See, Y. Song et al. Because k_{R}^{ph-mode} is a constant, the biaxial strain is directly proportional to frequency shift, i.e., ε_{B}∝−(ω−ω₀). A red shift corresponds to tensile strain (εB>0), whereas a blue shift corresponds to compressive strain (εB<0). FIG. 16 at c and d shows the spatial Raman maps of the A_{g}⁽³⁾ peak for samples A2 and B1. Both samples are structurally homogeneous with the A_{g}⁽³⁾ peak position varying within z0.50 cm⁻¹ wave number throughout the spatial map. The average of 100 peaks associated with the A_{g}⁽³⁾ phonon line taken over 20×20 μm² area is ≈198.70 cm⁻¹ for sample A2 and ≈198.25 cm⁻¹ for sample B1. In both cases, the samples show a red shift indicating tensile strain in the epilayers in reference to bulk (201) β-Ga2O3, with the tensile strain being higher for the latter case. Thus, the higher Raman shift or strain in sample B1 corroborates our observation of slightly increasing the lattice constants as 2θ peaks shift to a higher value by 0.050 in X-ray reflections. The 2θ (201) peak at 18.97° and Raman A, mode peak at 199.7 cm⁻¹ are reported for (201) β-Ga2O3 substrate. See, Y. Song et al. The tensile strain in sample A2 is found to be ≈0.87% from XRD with a relative Raman wave number shift of 0.50%, and in sample B1 is found to be ≈0.60% from XRD with a relative Raman wave number shift of 0.73% compared to (201) β-Ga2O3 substrate.

### Thermal Annealing and Stability of Ga2O3

We observed that the thermal annealing turned the mixed phase Ga2O3 (sample A2) into β-(AlxGa1 x)2O3 as confirmed by the change in the bandgap, XRD 2θ ω scans, and shift in (603) 2θ position from 58.85° to 59.42° with thermal annealing in the 900-1200° C. temperature range. The vacuum annealed β-Ga2O3 on sapphire, contrarily, recovered its 2θ peak position once cooled down, i.e., no structural change in vacuum annealed β-Ga2O3. See, F. Gucmann, P. Nádaždy, K. Hušeková, E. Dobroÿ cka, J. Priesol, F. Egyenes, A. Šatka, A. Rosová, M. Ťapajna, Mater. Sci. Semicond. Process. 2023, 156, 107289. The SIMS depth profile in thermally annealed Ga2O3 on sapphire in our case, indicates the presence of A1 throughout the ≈420 nm film when annealed at 1000° C. or higher temperature. The only source of aluminum is the sapphire substrate; thus, we conclude that A1-atoms from sapphire (α-Al2O3) diffused to Ga2O3, forming β-(AlxGa1 x)2O3 with thermal annealing. The FWHMs of (201) ω-RC for the 1200° C. annealed sample was ≈3.22°, which is like the unannealed Ga2O3. Thermally annealed Ga2O3 thin films were stable up to 1200° C. with no notable change in surface morphology. The surface roughness (9-10 nm) and average feature height (h≈41 nm) remained similar before and after annealing and comparable to those seen with vacuum annealing. See Id.

### Ga2O3 Growth on AlN/Sapphire Template

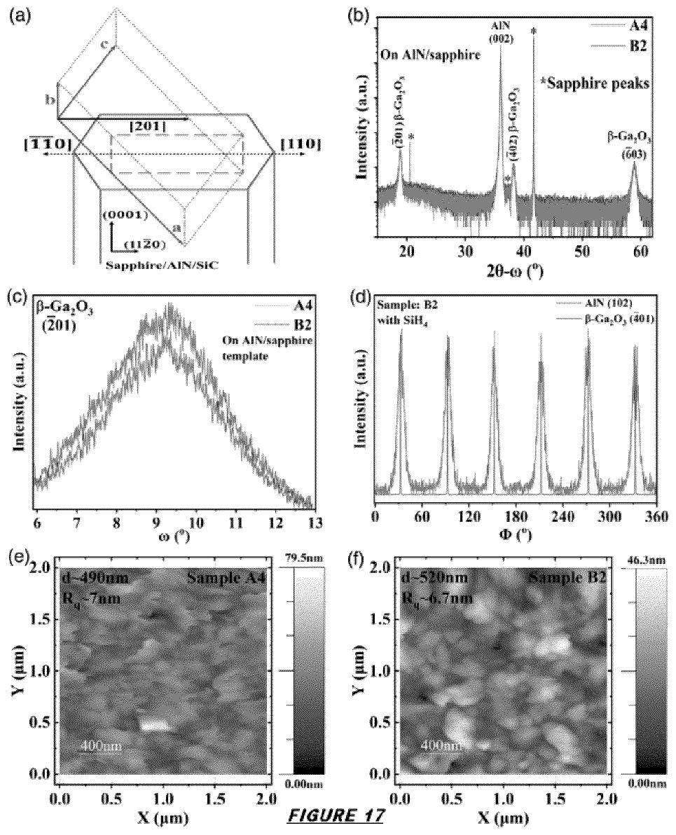

The c-plane sapphire, AlN, and silicon carbide (6H—SiC and 4H—SiC) have hexagonal crystal structures with (001) being the growth direction. β-Ga2O3 grows in (201) direction on c-plane sapphire as its (001) plane is parallel to (201) plane of β-Ga2O3, as shown in FIG. 17 at a. FIG. 17 shows at: a) β-Ga₂O₃ growth direction on a c-plane sapphire or AlN or 6H—SiC assuming a hexagonal structure. Ga₂O₃ on AlN/sapphire template; b) XRD 2θ-ω spectra; c) XRD rocking curves (ω-scan) of (201) β-Ga₂O₃ reflection. d) XRD Φ-scans of {401}-plane of β-Ga₂O₃ and {102}-plane of AlN for sample B2. AFM images of e) sample A4 [z-scale: 0-79.5 nm] and f) sample B2 [z-scale: 0-46.3 nm]. It is expected to have (201) β-Ga2O3/AlN or (201) β-Ga2O3/AlN/sapphire heteroepitaxy like GaN/AlN or GaN/AlN/sapphire heteroepitaxy. The AlN/sapphire templates are atomically smooth with an RMS roughness of 0.25 nm. These AlN templates have a bandgap of ≈6.10 eV with over 90% optical transparency. The full-width half maximum of 0.40 m thick AlN (102) RC is 0.36°. Considering the case of the AlN/sapphire template and AlN substrate, orthorhombic or pseudo-hexagonal ε-Ga2O3 (or κ-Ga2O3) MOCVD growths were reported. See, Y. Oshima et al., A. F. M. A. U. Bhuiyan et al, and W. Chen et al. Using the same growth processes of “A” and “B” thin film series for the epilayer structures shown in FIG. 10 at c and d on 0.4 m thick AlN/sapphire, we deposited ≈490 nm (sample A4/without SiH4) and ≈520 nm (sample B2/with SiH4) thick β-Ga2O3. Both A4 and B2 thin films have a bandgap of ≈4.8 eV. The resistivity on samples A4 and B2 are found to be 79.42 and 117.11 Ω-cm, respectively. This increase may result from SiOx formation, like the observation on sapphire, as discussed earlier. The 2θ-ω scan of sample A4 in FIG. 17 at b shows 2θ peaks at 18.86°, 20.47° 36.02°, 37.32°, 38.26°, 41.66°, 58.89° correspond to (201), (003), (002), (404), (402), (006), (603) of β-Ga2O3, α-Al2O3, AlN, α-Al2O3, β-Ga2O3, α-Al2O3, β-Ga2O3, respectively. The same 2θ peaks were found at the same positions in sample B2; hence, no tensile or compressive strain compared to sample A4. Phase stabilization is not required for Ga2O3 growth on the AlN template. FIG. 17 at c shows the (201) ω-RCs of β-Ga2O3 for samples A4 and B2. The (201) ω-peaks were measured at 9.20° in A4 and at 9.12° in B2. The FWHMs of (201) ω-RCs are 3.33° (A4), and 3.43° (B2), comparable to those grown on sapphire. The XRD Φ-scans on sample B2 are shown in FIG. 17 at d. The XRD Φ-scans on sample A4 show similar properties. Six {102}-plane diffraction peaks in both AlN templates with 600 separation, confirm the sixfold symmetry of the hexagonal AlN template. Six β-Ga2O3 {401}-plane strong peaks with similar intensities were measured in both samples. The six {401}-plane peaks indicate the presence of sixfold inplane rotational symmetry in β-Ga2O3 thin films on the AlN template. The six {401}-plane β-Ga2O3 peaks and six {102}-plane AlN peaks are at almost the same Φ positions. This suggests an excellent epitaxial relationship between β-Ga2O3 and AlN template with no rotation in the β-Ga2O3 basal plane with respect to AlN. Sample A4 has an RMS roughness of 7.0 nm as shown in FIG. 17 at e. The SiH4 flow changes the surface morphology, as shown in FIG. 17 at f, with an RMS roughness of 6.7 nm.

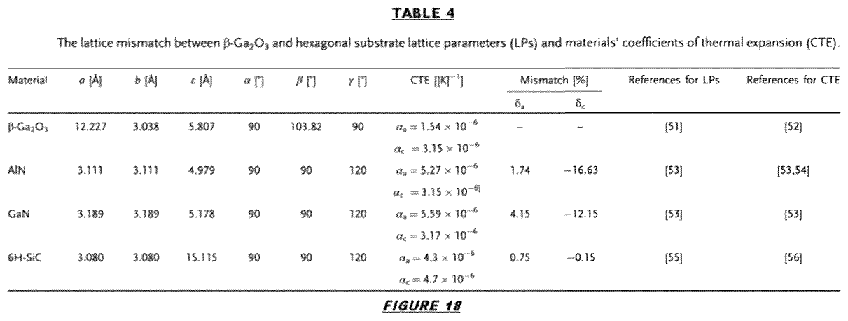

The Ga2O3 growth process described herein may be applied in bulk AlN, GaN, and SiC (0001) substrates. Lattice mismatch and coefficient of thermal expansion (CTE) should be considered for β-Ga2O3 heteroepitaxy on these thermally conducting substrates. See Table 4, FIG. 18. FIG. 18 shows Table 4—The lattice mismatch between β-Ga₂O₃ and hexagonal substrate lattice parameters (LPs) and materials' coefficients of thermal expansion (CTE). Table 4 summarizes the materials' CTEs and corresponding coincidental lattice mismatch for aGa₂O3 and cGa₂O3.

The lattice mismatch is calculated as

$$\text{?} = \frac{\text{?}}{\text{?}}$$

$$\text{?} \text{indicates text missing or illegible when filed}$$

×100% or

$$\text{?} = \frac{\text{?}}{\text{?}} ,$$

$$\text{?} \text{indicates text missing or illegible when filed}$$

×100% where aepi, cepi are a, c lattice parameters (LPs) of β-Ga2O3 and asub, csub are a, c LPs of substrates (AlN/GaN/6H—SiC). The m and n integers are calculated from the LPs ratio, aₑₚᵢ/a_{sub}=m/n for example.

In summary, we showed an alternative use of silicon for β-Ga2O3 MOCVD heteroepitaxy as a phase stabilizer in the form of silicon-oxygen (Si—O) bonding. This new approach can offer substantial advantages over thermal annealing for achieving monoclinic phase-pure gallium oxide (β-Ga2O3) on sapphire. Our results on AlN/sapphire templates suggest that the growth process reported herein may be replicable on thermally conductive bulk hexagonal substrates, such as AlN and SiC, that can resolve the low thermal conductivity issues related to Ga2O3 material system.

### Experimental Section

Ultraviolet-Visible (UV-Vis) Spectroscopy: The optical transmittance and absorbance spectra were acquired with a Gentech TU-1901 spectrophotometer in the 200-800 nm wavelength range.

X-ray Diffraction (XRD): Panalytical Empyrean high-resolution X-ray diffractometer (HR-XRD) with Cu_Kα X-ray source operated at 45 kV voltage, and 40 mA current was used for XRD scans. The 2θ ω scans were carried out between the 15° and 62° range, and ω scans were done from the 5.9° to ≈13° range.

Time-of-Flight Secondary Ion Mass Spectroscopy (ToF-SIMS): The TOF secondary ion mass spectroscopy (ToF-SIMS, Instrument: IONTOF ToF-SIMS 5-300) was used to identify chemical elements and complexes. Bismuth ion (B⁺) was used as the primary sputtering ion source. The SIMS analyses were performed over a 500×500 μm² area along the flattest possible crater.

van der Pauw Measurements: The van der Pauw/Hall measurements were performed by MMR technologies Hall measurement system equipped with an H-50 Hall van der Pauw controller and MPS-50 programmable magnet power supply. The contacts were made by soldering indium shots.

Scanning Electron Microscopy (SEM): The sample surface SEM images were taken using Zeiss Gemini500 FESEM operating at 5 kV acceleration voltage from a working distance of ≈10 mm at the indicated magnification scale in SEM images.

Atomic Force Microscopy (AFM): The surface morphology of thin films was observed with a Nanotec AFM equipped with a Dulcenia control unit and WSxM beta software.

Raman Spectroscopy: The vibrational modes and microstructural homogeneity were obtained from Raman spectroscopy using a Horiba Raman spectrometer. The laser excitation of 638 nm was used at 50× objective and a 25% incident power with an 1800 g mm⁻¹ grating. The spectrometer has a spectral resolution of 0.5 cm⁻¹.

Various modifications and variations of the described methods, compositions, and kits of the disclosure will be apparent to those skilled in the art without departing from the scope and spirit of the disclosure. Although the disclosure has been described in connection with specific embodiments, it will be understood that it is capable of further modifications and that the disclosure as claimed should not be unduly limited to such specific embodiments. Indeed, various modifications of the described modes for carrying out the disclosure that are obvious to those skilled in the art are intended to be within the scope of the disclosure. This application is intended to cover any variations, uses, or adaptations of the disclosure following, in general, the principles of the disclosure and including such departures from the present disclosure come within known customary practice within the art to which the disclosure pertains and may be applied to the essential features herein before set forth.

What is claimed is:

1. A method for growing Ga₂O₃ Growth on sapphire comprising:
employing a metal-organic chemical vapor deposition reactor;
introducing at least one sapphire template to the reactor;
using nitrogen as a carrier gas in the reactor to enable nitridation of the sapphire substrate;
introducing Trimethylaluminum as a nitrogen precursor and ammonia as an aluminum precursor to the reactor to form an aluminum nitrogen layer on the at least one sapphire template;
introducing Triethylgallium as a gallium precursor and oxygen as an oxygen precursor using nitrogen as a carrier gas in the reactor to form at least one gallium oxygen layer on the aluminum nitrogen layer; and
employing silane in the reactor as a silicon precursor contemporaneous with introduction of the Triethylgallium and the oxygen in the reactor.

2. The method of claim 1, wherein a reactor pressure and a substrate temperature are kept constant throughout growth.

3. The method of claim 1, wherein the aluminum nitrogen layer is formed via pulsed mode growth.

4. The method of claim 1, wherein the at least one gallium oxygen layer comprises at least one β-Ga₂O₃ layer.

5. The method of claim 4, wherein the at least one β-Ga₂O₃ layer comprises monoclinic phase-pure gallium oxide.

6. The method of claim 4, further comprising forming at least one SiOₓ complex in the at least one β-Ga₂O₃ via the introduction of silane into the reactor contemporaneous with the introduction of the Triethylgallium and the oxygen.

7. The method of claim 4, further comprising forming sixfold inplane rotational symmetry in the at least one β-Ga₂O₃ layer formed on the aluminum nitrogen layer.

8. The method of claim 1, wherein the method does not include thermal annealing.

9. The method of claim 1, wherein the sapphire template comprises c-plane sapphire.

10. A method for growing Ga₂O₃ layers on sapphire comprising:
employing a metal-organic chemical vapor deposition reactor;
introducing at least one sapphire template to the reactor;
using nitrogen as a carrier gas in the reactor to enable nitridation of the sapphire substrate;
forming at least one substrate layer onto the sapphire substrate wherein the at least one substrate layer comprises an aluminum nitrogen layer, a gallium nitrogen layer or a silicon carbon layer;
introducing Triethylgallium as a gallium precursor and oxygen as an oxygen precursor using nitrogen as a carrier gas in the reactor to form at least one gallium oxygen layer on the aluminum nitrogen layer; and
employing silane in the reactor as a silicon precursor contemporaneous with introduction of the Triethylgallium and the oxygen in the reactor.

11. The method of claim 10, wherein a reactor pressure and a substrate temperature are kept constant throughout growth.

12. The method of claim 10, wherein the aluminum nitrogen layer is formed via pulsed mode growth.

13. The method of claim 10, wherein the at least one gallium oxygen layer comprises at least one β-Ga₂O₃ layer.

14. The method of claim 13, wherein the at least one β-Ga₂O₃ layer comprises monoclinic phase-pure gallium oxide.

15. The method of claim 13, further comprising forming a SiOₓ complex in the at least one β-Ga₂O₃ layer via the introduction of silane into the reactor contemporaneous with the introduction of Triethylgallium and introduction of the oxygen.

16. The method of claim 13, further comprising forming sixfold inplane rotational symmetry in the at least one β-Ga₂O₃ layer formed on the aluminum nitrogen layer.

17. The method of claim 10, wherein the method does not include thermal annealing.

18. The method of claim 10, wherein the sapphire template comprises c-plane sapphire.
